(19) United States
(12) Patent Application Publication
(10) Pub. No.: US 2025/0323660 A1
(43) Pub. Date: Oct. 16, 2025

(54) ZONE-BASED THRESHOLD CALIBRATION IN DELAY-DOMAIN ANALOG-TO-DIGITAL CONVERTERS

(71) Applicant: Texas Instruments Incorporated, Dallas, TX (US)

(72) Inventors: Rishi Soundararajan, Bangalore (IN); Pavan Vemuri, Bangalore (IN); Visvesvaraya Appala Pentakota, Bangalore (IN)

(21) Appl. No.: 19/095,304

(22) Filed: Mar. 31, 2025

Related U.S. Application Data
(63) Continuation-in-part of application No. 18/174,187, filed on Feb. 24, 2023, now Pat. No. 12,355,460.

(51) Int. Cl. H03M 1/50; H03M 1/10; H03M 1/46

(52) U.S. Cl. CPC H03M 1/50; H03M 1/1009; H03M 1/46

(57) ABSTRACT

An analog-to-digital converter including a voltage-to-delay circuit, a plurality of residue stages coupled in a sequence, and select logic. A first residue stage generates a bit output and a residue delay signal, a second residue stage generates a bit output and a residue delay signal responsive to the residue delay signal from the first residue stage, and a third residue stage generates a bit output and a residue delay signal responsive to the residue delay signal from the second residue stage. The third residue stage includes a plurality of trim circuits, the selection of which is controlled by the bit output of two or more preceding residue stages in the sequence.

### CROSS-REFERENCE TO RELATED APPLICATIONS

This application claims priority under 35 U.S.C. § 120 as a continuation-in-part of copending and commonly assigned U.S. patent application Ser. No. 18/174,187, filed Feb. 24, 2023, said application incorporated herein by this reference.

### BACKGROUND

This relates to analog-to-digital converters, and more particularly relates to analog-to-digital converters that operate in part in the delay domain.

Analog-to-digital converter (ADC) circuits generate digital words or codes to represent levels of an input analog signal. One type of ADC is referred to as a “pipelined” ADC. A pipelined ADC includes a sequence of consecutive stages. Each stage evaluates one or two bits of the output word and forwards a remainder, or “residue,” to a next stage that resolves the next one or two less significant bits, and so on.

In system applications such as radio-frequency (RF) sampling receivers, radar systems, test and measurement equipment, and the like, input ADC circuitry must operate at a high sampling rate to accurately digitize the incoming high frequency analog signal. Due to architectural constraints, some pipelined ADCs may be limited in operating speed, and thus may not be suited for use in RF-sampling receivers.

To address this limitation of pipelined ADCs, a type of ADC referred to as a “time-domain” or “delay-domain” ADC has been developed. A delay domain ADC includes a voltage-to-delay (V2D) component and a time-to-digital converter (TDC) component. The V2D component expresses the received input voltage in terms of a signal delay, e.g., between transitions on two signal lines. The TDC component converts the signal delay output by the V2D component into a digital code word. Delay-domain analog-to-digital converters can be capable of high speed operation, and can require less chip area and power than other types of pipelined ADCs.

Examples of delay-domain analog-to-digital converters are described in U.S. Pat. Nos. 10,673,453; 10,778,243; 11,316,525; and 11,316,526; U.S. Patent Application Publication No. US 2024/0072820 A1; and U.S. Patent Application Publication No. US 2024/0171190 A1, all of which are commonly assigned herewith and incorporated herein by reference in their entirety.

In some implementations, the TDC component of the ADC is pipelined, with each stage receiving, from a previous stage, a delay residue signal in the form of a delay between two signals. In response to the input delay residue signal, the TDC stage generates one or more digital bits and a delay residue signal for the next stage in the sequence. As described in the above-incorporated U.S. Pat. Nos. 10,673,453 and 10,778,243 by way of example, each TDC stage can be realized by the combination of a delay comparator and a logic gate, without requiring residue amplifiers or reference amplifiers. This architecture provides a high speed ADC that is particularly efficient in chip area and power consumption. However, the delay profile of the delay comparator in each such TDC stage is highly non-linear (e.g., exponential), causing non-linearity in the output digital codes.

To correct for this non-linearity, many delay-domain ADCs linearize the analog-to-digital conversion using a look-up table to generate the output digital word, as described in the above-incorporated U.S. Pat. No. 11,316,525 and U.S. Patent Application Publication No. US 2024/0072820. In addition, calibration techniques for linearizing delay domain ADCs are described in the above-incorporated U.S. Pat. No. 11,316,525, U.S. Pat. No. 11,316,526, and U.S. Patent Application Publication No. US 2024/0171190 A1.

### SUMMARY

According to an example, a circuit includes an analog-to-digital converter includes a voltage-to-delay circuit, a plurality of residue stages coupled in a sequence; select logic; and digital circuitry. The voltage-to-delay circuit is configured to generate a delay signal at first and second outputs responsive to an input voltage. The plurality of residue stages includes a first residue stage having a first input coupled to the first output of the voltage-to-delay circuit, a second input coupled to the second output of the voltage-to-delay circuit, and first and second residue outputs; a second residue stage having a bit output and first and second residue outputs; a third residue stage having a first input coupled to the first residue output of the second residue stage, a second input coupled to the second residue output of the second residue stage, a bit output, and first and second residue outputs; and a fourth residue stage having a first input coupled to the first residue output of the third residue stage, a second input coupled to the second residue output of the third residue stage, and a bit output, the fourth residue stage including a plurality of trim circuits, each trim circuit having a select input. The select logic has inputs coupled to the bit outputs of the second and third residue stages and outputs coupled to the select inputs of the plurality of trim circuits of the fourth residue stage

According to another example, an analog-to-digital converter includes a voltage-to-delay circuit configured to generate a delay signal at first and second outputs responsive to an input voltage, and a time-to-digital circuit configured to generate a digital output word responsive to the delay signal from the voltage-to-delay circuit. The time-to-digital circuit includes a plurality of residue stages coupled in a sequence, each configured to generate a bit output responsive to a polarity of an input delay residue from a preceding residue stage in the sequence, and an output delay residue to a next residue stage in the sequence. One of the plurality of residue stages generates its output delay residue at a polarity based on a comparison of its input delay residue with one of a plurality of independently controlled null delay thresholds selected responsive to the bit outputs of at least two preceding residue stages in the sequence and to the polarity of its input delay residue.

According to another example, a system includes an analog front end, an analog-to-digital converter, and a controller. The analog-to-digital converter includes a voltage-to-delay circuit, a plurality of residue stages, select logic, and digital circuitry. The plurality of residue stages include a first residue stage having a first input coupled to the first output of the voltage-to-delay circuit and a second input coupled to the second output of the voltage-to-delay circuit; a second residue stage having a bit output and first and second residue outputs; a third residue stage having a first input coupled to the first residue output of the second residue stage and a second input coupled to the second residue output of the second residue stage; and a fourth residue stage having a first input coupled to a first residue output of the third residue stage, a second input coupled to a second residue output of the third residue stage, and a bit output. The fourth residue stage includes a plurality of trim circuits, each having a select input. The select logic has inputs coupled to the bit outputs of the second and third residue stages and outputs coupled to the select inputs of the plurality of trim circuits of the fourth residue stage.

Example technical advantages enabled by one or more of these examples include the ability to separately and independently calibrate each of multiple null delay thresholds defined by residue stages in a time-to-digital converter (TDC) component of a delay-domain analog-to-digital converter (ADC). Integral non-linearity can be substantially improved in high data rate, high precision ADCs. In some implementations, one or more of these examples enable the a look-up table for linearizing the digital output to be omitted from the ADC. Select logic for selecting individual trim circuits in the residue stages can operate asynchronously, within the stage delay of its associated residue stage.

Other example technical advantages enabled by this disclosure are apparent to those of ordinary skill in the art having reference to the following specification together with its drawings.

### BRIEF DESCRIPTION OF THE DRAWINGS

FIG. 1 is an electrical diagram, in block form, of an example delay-domain analog-to-digital converter (ADC).

FIG. 2 is an electrical diagram, in schematic form, of an example residue stage in the ADC of FIG. 1.

FIG. 3 is a plot of output delay residue relative to input delay residue in the example residue stage of FIG. 2.

FIG. 4 illustrates curves of residue delay versus input voltage at residue stages of the example ADC of FIG. 1.

FIG. 5 is an electrical diagram, in schematic form, of an example third stage residue stage in the ADC of FIG. 1.

FIGS. 6A and 6B are electrical diagrams, in schematic form, of trim circuits in the residue stage of FIG. 5.

FIG. 7 is an electrical diagram, in block form, of example trim select logic with residue stages of the ADC of FIG. 1.

FIG. 8 is an electrical diagram, in schematic form, of an example select logic stage in the trim select logic of FIG. 7.

FIG. 9 is an electrical diagram, in schematic form, of an example residue stage for some residue stages in the ADC of FIG. 1.

FIG. 10A is an electrical diagram, in schematic form, of a trim circuit in one of the residue stages of FIG. 9.

FIG. 10B is a plot of output delay residue relative to input delay residue in the example residue stage of FIG. 9.

FIG. 11A is an electrical diagram, in schematic form, of another example select logic stage in the trim select logic of FIG. 7.

FIG. 11B is an electrical diagram, in schematic form, of another example select logic stage in the trim select logic of FIG. 7.

FIG. 12 is a flow diagram illustrating an example method of calibrating the ADC of FIG. 1.

FIG. 13 is a flow diagram illustrating an example method of operating the ADC of FIG. 1.

FIG. 14 is an electrical diagram, in block form, of an example circuit including the ADC of FIG. 1.

The same reference numbers or other reference designators are used in the drawings to illustrate the same or similar (in function and/or structure) features.

### DETAILED DESCRIPTION

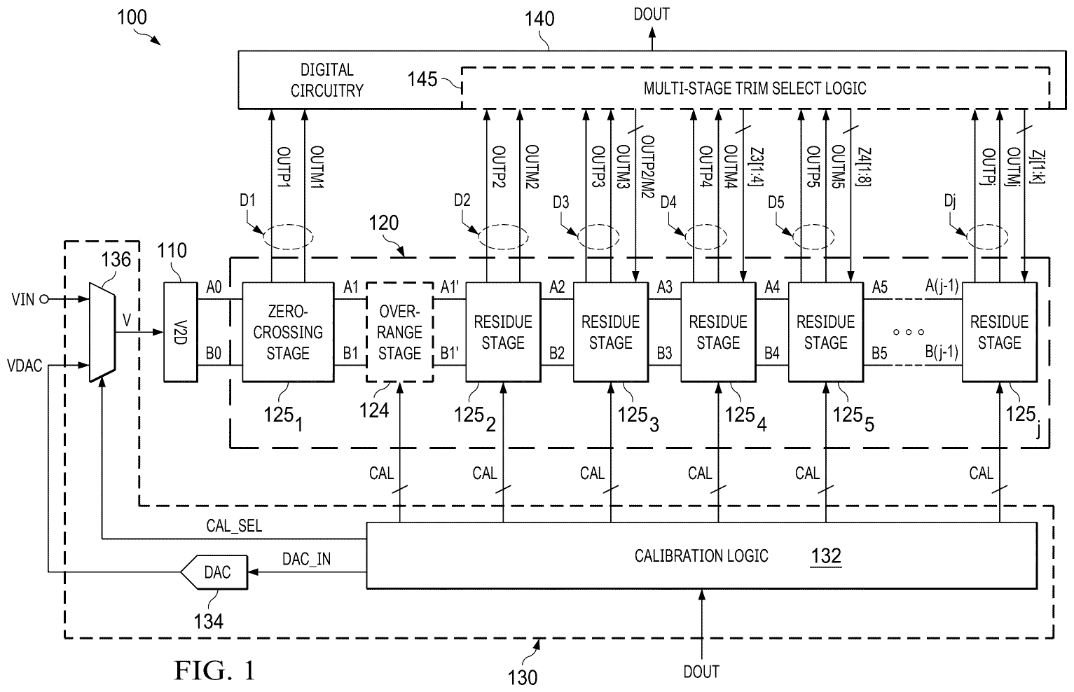

FIG. 1 illustrates an example delay domain ADC 100. ADC 100 includes a voltage-to-delay (V2D) component 110, a time-to-digital converter (TDC) component 120, digital circuitry 140, and calibration circuitry 130. TDC component 120 includes zero-crossing stage 125₁, over-range stage 124, and residue stages 125₂, 125₃, 125₄, 125₅, . . . , through 125ⱼ (generically or collectively referred to herein as residue stage or stages 125). Calibration circuitry 130 includes calibration logic 132, digital-to-analog converter (DAC) 134, and input multiplexer 136.

In the example of FIG. 1, input multiplexer 136 has one input coupled to input line VIN to receive an input voltage, for example as applied to an input terminal by a source external to ADC 100. Another input of input multiplexer 136 is coupled to signal line VDAC, which in turn is coupled to an output of DAC 134. A control input of input multiplexer 136 is coupled to signal line CAL_SEL, which in turn is coupled to an output of calibration logic 132. Input multiplexer 136 has an output coupled to signal line V, which in turn is coupled to an input of V2D component 110.

Calibration logic 132 outputs a select signal to the control input of input multiplexer 136 via signal line CAL_SEL, and outputs a calibration voltage to DAC 134 as a digital word on signal line(s) DAC_IN. In normal operation of ADC 100, the select signal from calibration logic 132 causes input multiplexer 136 to select the voltage on input line VIN to be forwarded on line V to the input of V2D component 110. In a calibration operation, a select signal on signal line CAL_SEL causes input multiplexer 136 to output the voltage at signal line VDAC onto line V. Calibration logic 132 also has outputs coupled to one or more signal lines CAL, for the communication of calibration signals to TDC component 120.

The input voltage on line VIN corresponds to an analog voltage that is to be converted to a digital word DOUT. For example, this analog voltage may be a sample of a time-varying signal, for example as obtained by a sample-and-hold circuit (not shown). In the normal operation of ADC 100, input multiplexer 136 applies the voltage on line VIN to the input of V2D component 110.

V2D component 110 in this example has one output coupled to delay signal line A0, and another output coupled to delay signal line B0. V2D component 110 is configured to generate a delay-domain signal on delay signal lines A0, B0 corresponding to the amplitude of the voltage on line V. For example, the delay-domain signal generated by V2D component 110 may be in the form of logic level transitions on delay signal lines A0, B0 having a relative delay corresponding to the amplitude of input voltage VIN. Examples of V2D component 110 suitable for use in ADC 100 are provided in U.S. Pat. Nos. 10,673,456, 11,316,526, U.S. Patent Application Publication No. US 2024/0072820, and U.S. application Ser. No. 18/498,358, filed Oct. 31, 2023 and entitled “Voltage-to-Delay Converter”, all commonly assigned herewith and incorporated herein by this reference.

Signal lines A0, B0 are coupled to corresponding inputs of time-to-digital converter (TDC) component 120. The multiple stages in TDC component 120 operate together with digital circuitry 140 to encode j bits of digital output word DOUT in response to the relative time delay between the logic transitions at lines A0, B0, and thus in response to the level of the analog voltage on line V.

In the example of FIG. 1, TDC component 120 of ADC 100 includes zero-crossing stage 125₁, over-range stage 124, and residue stages 125 coupled in a sequence. Zero-crossing stage 125₁ has inputs coupled to signal lines A0, B0 from V2D component 110, and outputs coupled to residue signal lines A1, B1. Zero-crossing stage 125₁ also has an output (referred to in this description as bit output D1) coupled to an input of digital circuitry 140. In this example, the bit output D1 is implemented by a pair of intermediate outputs OUTP1, OUTM1 of zero-crossing stage 125, at one of which zero-crossing stage 125₁ outputs a logic level transition in response to the delay signal communicated by delay signal lines A0, B0. Zero-crossing stage 125₁ also has outputs coupled to residue signal lines A1, B1. Over-range stage 124 and residue stages 125₂ through 125ⱼ in this example each also have inputs coupled to one or more calibration signal lines CAL from calibration logic 132 as shown in FIG. 1.

Zero-crossing stage 125₁ may be constructed similarly as residue stages 125₂ through 125ⱼ described below. As described in the above-incorporated U.S. Patent Application Publication No. US 2024/0171190 A1, the state (“0” or “1”) of the signal generated by zero-crossing stage 125₁ at its bit output DI corresponds to the polarity of the delay signal at delay signal lines A0, B0, for example indicating whether a logic level transition at delay signal line A0 leads or lags a logic level transition at delay signal line B0.

Alternatively, the first residue stage of TDC component 120 may be a multi-bit stage, an example of which is described in the above-incorporated U.S. Pat. No. 11,316,526. In that case, the multi-bit residue stage generates k bits (k≥1) of digital information that are forwarded to digital circuitry 140 on corresponding signal lines.

Also, in response to the delay signal at delay signal lines A0, B0, zero-crossing stage 125₁ generates a delay residue signal at its outputs coupled to residue signal lines A1, B1. This delay residue signal is in the form of logic level transitions at residue signal lines A1, B1 with a relative delay corresponding to the residue in the input delay signal relative to the zero-crossing threshold. The outputs of zero-crossing stage 125₁ coupled to residue signal lines A1, B1 may be referred to in this specification as “residue outputs,” as distinct from the bit output D1 (e.g., intermediate outputs OUTP1, OUTM1), which presents a digital-domain signal (e.g., “0” and “1” logic levels).

In ADC 100 according to this example, over-range stage 124 has inputs coupled to residue signal lines A1, B1, and has outputs coupled to residue signal lines A1′, B1′. Over-range stage 124 is an optional stage provided in this example to introduce gain at extreme values of the delay-domain signal at residue signal lines A0, B0, in order to improve both linearity and the signal-to-quantization-noise ratio (SQNR) of ADC 100. An example of the construction and operation of this optional over-range stage 124 is described in commonly assigned U.S. application Ser. No. 18/524,652, filed Nov. 30, 2023, entitled “Analog-to-Digital Converter with an Over-Range Stage,” and incorporated herein by this reference. Residue signal lines A1′, B1′ are coupled to inputs of residue stage 125₂.

In implementations in which optional over-range stage 124 is not included, residue signal lines A1, B1 from the residue outputs of zero-crossing stage 125₁ are coupled to inputs of residue stage 125₂.

In the sequence of residue stages 125 in this example, the outputs of residue stage 125₂ are coupled to residue signal lines A2, B2. Residue stage 125₃ has inputs coupled to residue signal lines A2, B2, and outputs coupled to residue signal lines A3, B3. Residue stage 125₄ has inputs coupled to residue signal lines A3, B3, and outputs coupled to residue signal lines A4, B4. This pipelined coupling of residue stages 125 continues in sequence through the j^{th} residue stage 125ⱼ. Each residue stage 125₂ through 125ⱼ produces a corresponding bit output D2 through Dj to digital circuitry 140, such that the number j of residue stages 125 corresponds to the resolution of ADC 100.

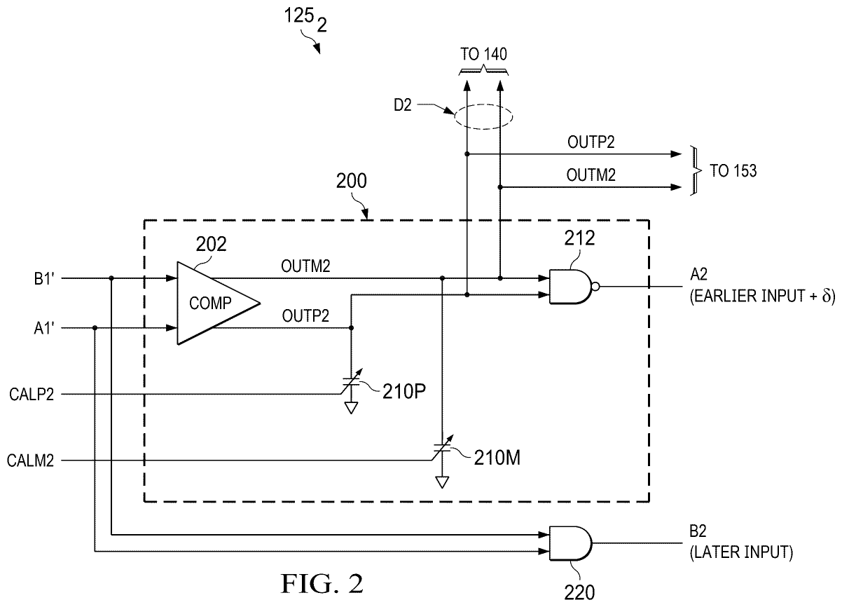

FIG. 2 illustrates the construction of residue stage 125₂ according to an example. Residue stage 125₂ includes delay comparator 200 and logic gate 220. Delay comparator 200 includes comparator 202 and logic gate 212. Logic gate 212 in this example is a NAND gate. Logic gate 220 in this example is an AND gate. Residue stage 125₂ also includes variable capacitors 210P and 210M.

Comparator 202 in delay comparator 200 has an input coupled to residue signal line A1′, and another input coupled to residue signal line B1′. Comparator 202 has two outputs, which in this example serve as intermediate outputs OUTP2, OUTM2 of residue stage 125₂. Logic gate 212 has inputs coupled to intermediate outputs OUTP2, OUTM2, and an output coupled to residue signal line A2. Logic gate 220 has inputs coupled to residue signal lines A1′, B1′, and an output coupled to residue signal line B2. As shown in FIG. 1, intermediate outputs OUTP2, OUTM2 are coupled to inputs of digital circuitry 140, and residue signal lines A2, B2 are coupled to inputs of the next residue stage 125₃ in the pipelined sequence of TDC component 120.

The above-incorporated U.S. Patent Application Publication No. US 2024/01771190A1 describes an example construction suitable for residue stage 125₂ and the other residue stages 125 in TDC component 120 of example ADC 100.

The following description of the operation of TDC component 120 adopts a logic convention in which the delay residue received by comparator 202 is in the form of low-to-high logic transitions on residue signal lines A1′, B1′ having a relative delay corresponding to the delay residue output by zero-crossing stage 125₁ (gain-adjusted by over-range stage 124, if included). In response to a low-to-high transition at residue signal line A1′ that leads a low-to-high transition at residue signal line B1′, comparator 202 drives a high-to-low transition at intermediate output OUTM2 while holding intermediate output OUTP2 high. For purposes of this description, the high-to-low transition at intermediate output OUTM2 corresponds to bit output D2=1 from residue stage 125₂. Conversely, in response to a low-to-high transition at residue signal line B1′ that leads a low-to-high transition at residue signal line A1′, comparator 202 drives a high-to-low transition at intermediate output OUTP2 while holding intermediate output OUTM2 high. For purposes of this description, the high-to-low transition at intermediate output OUTP2 corresponds to bit output D2=0 from residue stage 125₂. As described in the above-incorporated U.S. Patent Application Publication No. US 2024/01771190A1, comparator 202 may include a barrier circuit that determines its response (e.g., delay) to transitions at residue signal lines A1′, B1′.

In this example, logic gate 212 is configured as a NAND gate. Accordingly, logic gate 212 drives a low-to-high transition at residue signal line A2 in response to either of intermediate outputs OUTP2, OUTM2 of comparator 202 making a high-to-low transition. Stated another way, residue stage 125₂ drives a transition at residue signal line A2 in response to the earlier of the transitions at residue signal lines A1′, B1′.

Logic gate 220 has inputs coupled to residue signal lines A1′, B1′, and an output coupled to residue signal line B2. In this example, logic gate 220 is configured as an AND gate. Accordingly, logic gate 220 drives a low-to-high transition at residue signal line B2 in response to the later of the low-to-high transitions at residue signal lines A1′, B1′.

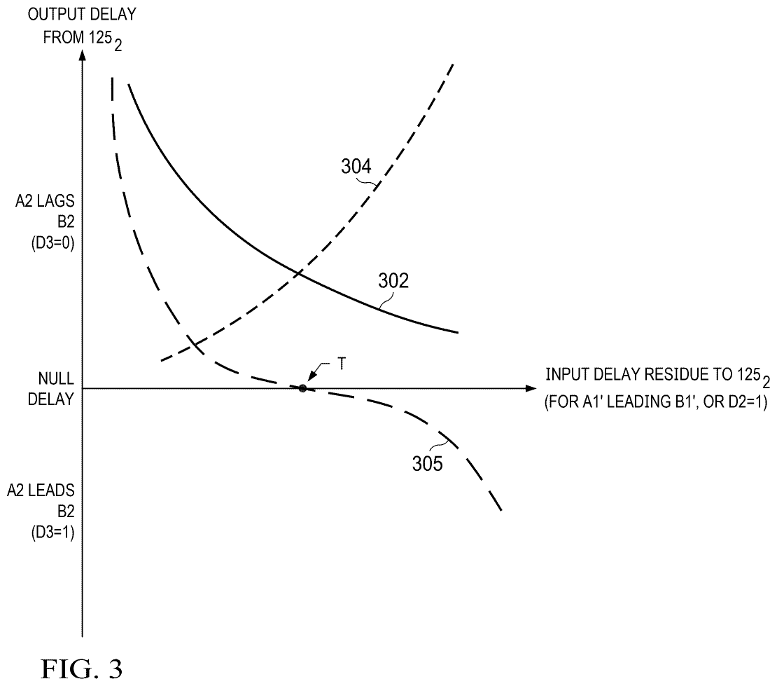

FIG. 3 illustrates the relationship of the delay residue as output by residue stage 125₂ on residue signal lines A2, B2 in response to the input delay residue received at residue signal lines A1′, B1′, for the case in which the transition at residue signal line A1′ leads the transition at residue signal line B1′ (e.g., bit output D2, as determined by residue stage 125₂, is a “1”). This relationship for the case of residue signal line A1′ lagging residue signal line B1′ (e.g., bit output D2=0) is expressed by mirror images of the curves of FIG. 3, reflected about the vertical axis.

This relationship of output delay residue to input delay residue is determined by the relative responses of delay comparator 200 and logic gate 220 to transitions at residue signal lines A1′, B1′. In this example, the response of delay comparator 200 to the relative delay between transitions at input residue signal lines A1′, B1′ generally follows an inverse logarithmic function, as shown by curve 302. As such, a shorter input delay residue to delay comparator 200 results in a longer output delay in the transition at residue signal line A2, and vice versa. Curve 304 illustrates the delay of the transition at output residue signal line B2 as generated by logic function 220 in response to the later of the input transitions at residue signal lines A1′, B1′. In the example of ADC 100 in which over-range stage 124 is included, response curve 304 has an exponential shape, due to the exponential gain characteristic of over-range stage 124. For implementations of ADC 100 not including over-range stage 124, the response of logic gate 220 is generally a linear function. In either case, a shorter input delay to logic gate 220 results in a shorter output delay in the transition at residue signal line B2, and vice versa.

The delay residue output by residue stage 125₂ to the next residue stage 125₃ is expressed by the relative delay of transitions at residue signal lines A2, B2, which corresponds to the difference in the delay response of delay comparator 200 and logic gate 220. Curve 305 of FIG. 3 illustrates this relative delay based on the difference between curves 302 and 304 in response to the input delay residue to residue stage 125₂, for the case of the transition at residue signal line A1′ leading that at residue signal line B1′ (e.g., bit output D2=1). Negative values along curve 305 correspond to delay comparator 200 (e.g., logic gate 212) outputting a transition at residue signal line A2 in advance of (leading) the transition output by logic gate 220 at residue signal line B2. Conversely, positive values along curve 305 correspond to logic gate 220 outputting a transition at residue signal line B2 leading that output by logic gate 212 at residue signal line A2.

The input delay residue value at which curve 305 of FIG. 3 crosses the null delay axis (e.g., zero relative delay between transitions at residue signal lines A2 and B2) sets the null delay threshold T for the next residue stage 125₃ in its determination of the value of its bit output D3. Referring to FIG. 2, variable capacitors 210P, 210M are provided in residue stage 125₂ for calibration of this null delay threshold T, for example as the result of a calibration routine. Variable capacitor 210P has one terminal coupled to intermediate output OUTP2 at an output of comparator 202, and another terminal coupled to a common terminal (e.g., at circuit ground). Variable capacitor 210M has one terminal coupled to intermediate output OUTM2 at an output of comparator 202, and another terminal coupled to the common terminal (e.g., at circuit ground). Variable capacitors 210P, 210M have control inputs coupled to calibration signal lines CALP2, CALM2, which in turn are coupled to outputs of calibration logic 132 (FIG. 1). Variable capacitors 210P, 210M may each be constructed as a switched-capacitor array, or in another arrangement.

In this example, adjustment of variable capacitors 210P or 210M to increase or decrease capacitance adds or removes delay, respectively, in the signal output by delay comparator 200 onto residue signal line A2, in response to the first of the signals received at residue signal lines A1′ and B1′. For example, the adjustment of variable capacitors 210P or 210M effectively shifts the non-linear response of delay comparator 200 to the first of the input signals at residue signal lines A1′, B1′. This non-linear response is illustrated by curve 305 of FIG. 3 for the case of the input signal at residue signal line A1′ leading that at residue signal line B1′. Adjustment of variable capacitor 210M horizontally shifts curve 305, and thus shifts the null delay threshold T along the horizontal axis. Adjustment of variable capacitor 210P would similarly shift the null delay threshold for the case of a leading signal received at residue signal line B1′. Accordingly, the timing of a transition at residue signal line A2 from delay comparator 200 in response to the residue value communicated by input residue signal lines A1′, B1′ can be calibrated by adjustment of the capacitance of variable capacitors 210P, 210M. Optionally, a variable capacitor or the like may also be included in logic gate 220 to adjust its response to the later of the transitions at residue signal lines A1′, B1′.

The above-incorporated U.S. Patent Application Publication No. US2024/0171190 describes various calibration approaches for delay-domain ADCs such as example ADC 100 of FIG. 1. In a general sense, calibration may be performed by applying a known input voltage to the ADC, and then adjusting delay in one or more bit stages of the TDC stage to obtain a correct digital output for that known input voltage. For ADC 100 of FIG. 1, the application of a known input voltage may be performed by calibration logic 132 providing a calibration voltage on signal line VDAC and a control signal on signal line CAL_SEL causing input multiplexer 136 to select signal line VDAC for output to V2D component 110 for conversion by ADC 100. Calibration logic 132 compares the converted digital word from digital output DOUT of digital circuitry 140, and issues calibration signals to over-range stage 124, and residue stages 125₂, 125₃, 125₄, 125₅, . . . , through 125ⱼ as appropriate to trim the response of those stages, for example by adjusting the capacitance of variable capacitors (e.g., variable capacitors 210P, 210M in residue stage 125₂.

The other residue stages 125₃ through 125ⱼ in TDC component 120 are constructed and operate in a similar manner as residue stage 125₂. However, the input delay residue range evaluated by each successive residue stage 125 covers one-half of the delay residue range evaluated by the previous stage.

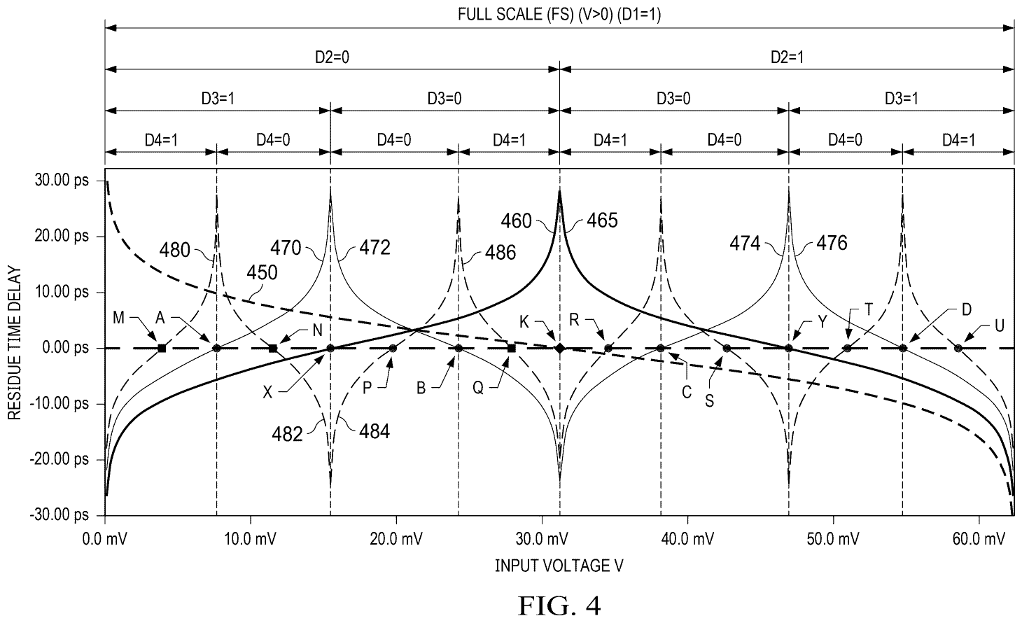

FIG. 4 illustrates a series of example plots of input and output residue delay versus input voltage V at residue stages 125₂, 125₃, 125₄, and 125₅ in TDC component 120 of delay-domain ADC 100, over the (positive) full scale range of input voltage V. In this example, the full scale of the ADC is +62 mV. Curve 450 of FIG. 4 illustrates the relationship of the input delay residue value applied on residue signal lines A1′, B1′ to residue stage 125₂ over the range of positive input voltage V (sign bit D1=1). As shown in FIG. 4, null delay threshold K is present at about ½ of full scale (FS), based upon which residue stage 125₂ determines the value of its bit output D2.

Curve 460 of FIG. 4 illustrates the delay residue at residue signal lines A2, B2 from residue stage 125₂ for input voltage V in the range from 0 mV to ½ FS (bit D2=0). The null delay threshold X of curve 460 is nominally at a value of ¼ FS. Similarly, curve 465 illustrates the delay residue at residue signal lines A2, B2 from residue stage 125₂ for input voltage V in the range from ½ FS to FS (bit D2=1). Curve 465 has a null delay threshold Y at a value of ¾ FS. Curve 465 of FIG. 4 corresponds to curve 305 in the example of FIG. 3.

As described above relative to FIG. 2 and in above-incorporated U.S. Patent Application Publication No. US 2024/0171190, calibration of residue stage 125₂ is performed by adjusting the capacitances of variable capacitors 210P, 210M. This allows the calibration of null delay thresholds X and Y separately from one another. For example, adjustment of the capacitance of variable capacitor 210P shifts null delay threshold Y for the case in which comparator 202 drives intermediate output OUTM2 low (e.g., bit output D2=1; A1′ leads B1′), without affecting null delay threshold X. Similarly, adjustment of the capacitance of variable capacitor 210M shifts null delay threshold X for the case in which comparator 202 drives intermediate output OUTP2 low (e.g., bit output D2=0; A1′ lags B1′), without affecting null delay threshold Y. Such calibration of residue stage 125₂ can set both of null delay thresholds X and Y to correspond to the ¼ FS and ¾ FS points of the input voltage range, respectively.

Accordingly, residue stage 125₂ has two separately calibratable null delay thresholds, corresponding to two non-linear relationships of output delay residue in response to input delay residue. The one of these two null delay thresholds to be applied by residue stage 125₂ in response to a given input delay residue is selected according to the bit result (bit D2) obtained by residue stage 125₂ itself, namely according to which signal transition (on input residue signal lines A1′, B1′) leads the other.

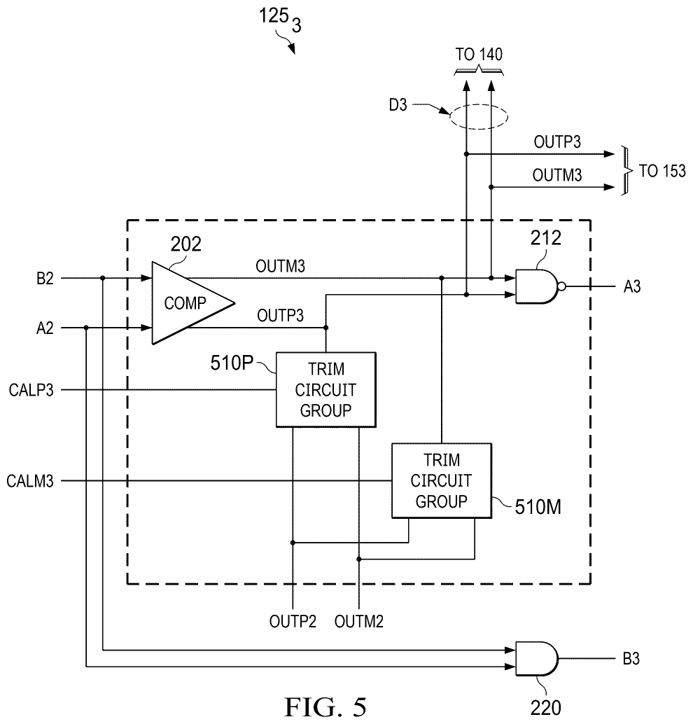

FIG. 5 illustrates the construction of the next residue stage 125₃ according to an example. The same reference numbers are used in FIG. 5 to illustrate those features in residue stage 125₃ that are also present in residue stage 125₂ of FIG. 2. As such, residue stage 125₃ includes delay comparator 200 and logic gate 220. Delay comparator 200 includes comparator 202 and logic gate 212. Logic gate 212 is a NAND gate in this example. Logic gate 220 in this example is an AND gate in this example. Residue stage 125₃ also includes trim circuit groups 510P and 510M.

In the case of residue stage 125₃, comparator 202 in delay comparator 200 has an input coupled to residue signal line A2, another input coupled to residue signal line B2, and intermediate outputs OUTP3, OUTM3. Logic gate 212 has inputs coupled to intermediate outputs OUTP3, OUTM3, and an output coupled to residue signal line A3. Logic gate 220 of residue stage 125₃ has inputs coupled to residue signal lines A2, B2, and an output coupled to residue signal line B3. Intermediate outputs OUTP3, OUTM3 are coupled to inputs of digital circuitry 140, and residue signal lines A3, B3 are coupled to inputs of the next residue stage 125₄ in the pipelined sequence of TDC component 120 (FIG. 1). The above-incorporated U.S. Patent Application Publication No. US 2024/01771190A1 further describes a residue stage construction suitable for residue stage 125₃.

In this example, residue stage 125₃ is configured to have four separately calibratable non-linear relationships of output delay residue to input delay residue (e.g., shown in FIG. 4 as curves 470, 472, 474, and 476), and thus four separately calibratable null delay thresholds (e.g., shown in FIG. 4 at points A, B, C, and D). The one of these four null delay thresholds to be applied by residue stage 125₂ in response to a given input delay residue is selected according to the combination of the bit result (bit D2) from residue stage 125₂ with the bit result (bit D3) obtained by residue stage 125₃ itself (e.g., which signal transition on input residue signal lines A2, B2 leads the other). For example, if the bit results from residue stages 125₂ and 125₃ are D2=0 and D3=1, the null delay threshold that determines the bit result from the next residue stage 125₄ is shown in FIG. 4 at point A on curve 470. In the example of FIG. 5, these four separately calibratable null delay thresholds are determined by trim circuits in trim circuit groups 510P and 510M.

In residue stage 125₃ of FIG. 5, trim circuit group 510P is coupled to intermediate output OUTP3 and trim circuit group 510M is coupled to intermediate output OUTM3. Trim circuit group 510P has one or more inputs coupled to calibration signal line(s) CALP3, and an input coupled to intermediate output OUTP2 from residue stage 125₂. Similarly, trim circuit group 510M has one or more inputs coupled to calibration signal line(s) CALM3, and an input coupled to intermediate output OUTM2 from residue stage 125₂. Intermediate outputs OUTP2, OUTM2 may be directly coupled to trim circuit groups 510P, 510M, respectively, or may be coupled through trim select logic 145.

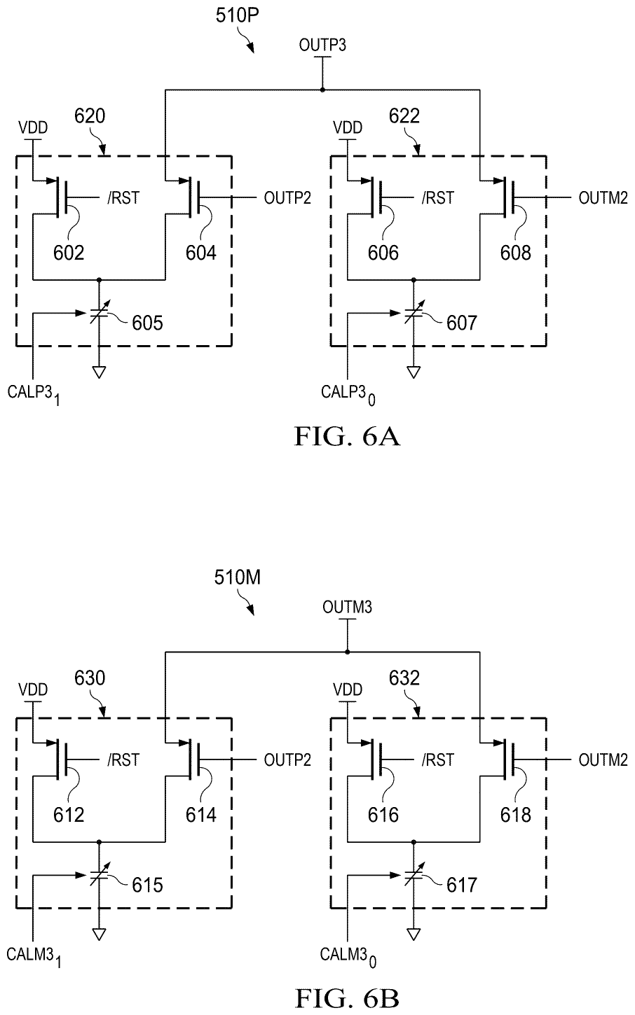

FIGS. 6A and 6B illustrate examples of trim circuit groups 510P, 510M, respectively. Trim circuit group 510P includes trim circuits 620 and 622. Trim circuit 620 includes p-channel metal-oxide-semiconductor (PMOS) transistor 602, 604, and variable capacitor 605. Trim circuit 622 includes PMOS transistors 606, 608, and variable capacitor 607. Trim circuit group 510M includes trim circuits 630 and 632. Trim circuit 630 includes PMOS transistors 612, 614, and variable capacitor 615. Trim circuit 632 includes PMOS transistors 616, 618, and variable capacitor 617. PMOS transistors 602, 604, 606, 608, 612, 614, 616, and 618 serve as switches or switching devices in this example, and as such may alternatively be implemented as n-channel MOS (NMOS) transistors, or another type of transistor, pass gate, or other switching device. Variable capacitors 605, 607, 615, and 617 may be implemented as switched-capacitor arrays, or in other arrangements of variable capacitors.

In trim circuit 620 of FIG. 6A, variable capacitor 605 has one terminal coupled to a common terminal (e.g., circuit ground) and another terminal coupled to terminals (e.g., drains) of PMOS transistors 602 and 604. PMOS transistor 602 has another terminal (e.g., a source) coupled to a power supply terminal (e.g., VDD) and a control terminal (e.g., a gate) receiving reset signal RST, for example from an output of digital circuitry 140 or other control and timing logic in ADC 100. Similarly, PMOS transistor 604 has a source coupled to intermediate output OUTP3 and a gate coupled to intermediate output OUTP2 of residue stage 125₂. In trim circuit 622, variable capacitor 607 has one terminal coupled to a common terminal (e.g., circuit ground) and another terminal coupled to drains of PMOS transistors 606, 608. PMOS transistor 606 has a source coupled to the VDD power supply terminal, and a gate receiving reset signal RST. PMOS transistor 608 has another terminal coupled to intermediate output OUTP3 and a gate coupled to intermediate output OUTM2 of residue stage 125₂. Variable capacitors 605 and 607 have capacitances selected in response to digital calibration words from calibration logic 132, communicated on calibration signal lines CALP3₁, CALP3₀, respectively.

Similarly, trim circuit 630 of FIG. 6B includes variable capacitor 615 with one terminal coupled to a common terminal (e.g., circuit ground) and another terminal coupled to drains of PMOS transistor 612 and 614. PMOS transistor 612 has a source coupled to the VDD power supply terminal and a gate receiving reset signal RST. PMOS transistor 614 has another terminal coupled to intermediate output OUTM3 and a gate coupled to intermediate output OUTP2 of residue stage 125₂. Trim circuit 632 includes variable capacitor 617 with one terminal coupled to a common terminal (e.g., circuit ground) and another terminal coupled to drains of PMOS transistors 616, 618. PMOS transistor 616 has a source coupled to the VDD power supply terminal, and a gate receiving reset signal RST. PMOS transistor 618 has source terminal coupled to intermediate output OUTM3 and a gate coupled to intermediate output OUTM2 of residue stage 125₂. Variable capacitors 615 and 617 have capacitances selected in response to digital calibration words from calibration logic 132, communicated on calibration signal lines CALM3₁, CALM3₀, respectively.

In normal operation, reset transistors 602, 606, 612, 616 are turned on by (negative logic) reset signal/RST. For example, digital circuitry 140 may issue reset signal/RST between sample conversions. In each instance, the top plates of corresponding variable capacitors 605, 607, 615, 617 are biased to the VDD power supply voltage in preparation for each conversion operation by ADC 100, ensuring a constant initial condition for each sample conversion.

Following this reset, according to this example, the capacitance applied by trim circuit 622 to intermediate output OUTP3 in a given conversion is that of variable capacitor 607 in response to intermediate output OUTM2 from residue stage 125₂ at a low level, which turns on PMOS transistor 608. This occurs in the event of bit output D2=1 from residue stage 125₂. Conversely, the capacitance applied by trim circuit 620 to intermediate output OUTP3 is that of variable capacitor 605 in response to intermediate output OUTP2 from residue stage 125₂ at a low logic level, turning on PMOS transistor 604, which occurs in the event of bit output D2=0 from residue stage 125₂. Similarly, the capacitance applied by trim circuit 632 to intermediate output OUTM3 is that of variable capacitor 617 if intermediate output OUTM2 in residue stage 125₂ is at a low logic level (bit output D2=1), and the capacitance applied by trim circuit 630 is that of variable capacitor 615 if intermediate output OUTP2 from residue stage 125₂ is at a high logic level (bit output D2=0).

Accordingly, the bit output result from residue stage 125₂ along with the bit output result of residue stage 125₃ itself determine the selection of the one of variable capacitors 605, 607, 615, 617 that affects the response of residue stage 125₃ in generating its output delay residue as follows:

TABLE 1

| | | Variable capacitor | Null delay |
|---|---|---|---|
| | | selected in residue | threshold |
| Bit output D2 | Bit output D3 | stage 125₃ | point |
| 0 | 0 | 615 | B |
| 0 | 1 | 607 | A |
| 1 | 0 | 617 | C |
| 1 | 1 | 605 | D |

Referring to FIG. 4, curve 470 illustrates the delay residue at residue signal lines A3, B3 from residue stage 125₃ versus input voltage V in the range from 0 mV to ¼ FS (bit outputs D2=0 and D3=1), with a null delay threshold A nominally at a value of ⅛ FS. Curve 472 illustrates the delay residue at residue signal lines A3, B3 for input voltage V in the range from ¼ FS to ½ FS (bit outputs D2=0 and D3=1), with a null delay threshold B nominally at ⅜ FS. Curve 474 illustrates the delay residue at residue signal lines A3, B3 from residue stage 125₃ for input voltage V in the range from ½ FS to ¾ FS (bit outputs D2=1 and D3=0), with a null delay threshold C nominally at ⅝ FS. Curve 476 illustrates the delay residue at residue signal lines A3, B3 for input voltage V in the range from ¾ FS to FS (bit outputs D2=1 and D3=1), with a null delay threshold D nominally at ⅞ FS. In calibration, the capacitances of variable capacitors 605, 607, 615, 617 may be individually selected in response to calibration signals from calibration logic 132 via calibration signal lines CALP3₁, CALP3₀, CALM3₁, and CALM3₀, respectively. Accordingly, this construction of trim circuits 622, 630, 632, 620 in residue stage 125₃ enables independent calibration of the four null delay thresholds A, B, C, D corresponding to ⅛ FS, ⅜ FS, ⅝ FS, and ⅞ FS, respectively, as shown in FIG. 4.

As evident from FIG. 4, each successive residue stage 125 in the sequence of TDC component 120 generates an output delay residue for a range of input voltage V that is one-half that evaluated by the previous residue stage 125 in the sequence. For the next residue stage 125₄, curve 480 illustrates the delay residue at residue signal lines A4, B4 from residue stage 125₄ for range from 0 mV to ⅛ FS (D2=0, D3=1, D4=1), with a null delay threshold M nominally at 1/16 FS. Curve 482 illustrates the delay residue at residue signal lines A4, B4 for input voltage V in the range from ⅛ FS to ¼ FS (D2=0, D3=1, D4=0), with a null delay threshold N nominally at 3/16 FS, curve 484 illustrates the delay residue at residue signal lines A4, B4 for input voltage V in the range from ¼ FS to ⅜ FS (D2=0, D3=0, D4=0), with a null delay threshold P nominally at 5/16 FS, and curve 486 illustrates the delay residue at residue signal lines A4, B4 for input voltage V in the range from ⅜ FS to ½ FS (DO=1, D3=0, and D4=1), with a null delay threshold Q nominally at 7/16 FS. Four more curves of delay residue at residue signal lines A4, B4, similarly cover the four sub-ranges of input voltage V from ½ FS to FS (D2=1), with null delay thresholds R, S, T, U.

In TDC component 120 of ADC 100 according to this example, one or more of the successive residue stages 125 (e.g., residue stages 125₃ through 125ⱼ) exhibit multiple separately calibratable non-linear relationships of output delay residue to input delay residue, each corresponding to a different sub-range or sub-ranges of input voltage, and thus multiple separately calibratable null delay thresholds. For residue stage 125₄ and later, the selection of the one of these multiple null delay thresholds to be applied in response to a given input delay residue is selected according to the combination of the bit result from two or more preceding residue stages 125 in the pipeline, along with the bit result obtained by that residue stage itself.

Various approaches to implementing multiple null delay thresholds in a given residue stage 125 are contemplated. For example, each residue stage 125 may include a switched capacitor array in which a combination of capacitances is selected (e.g., by static or dynamic logic) for each input voltage sample. According to the example of ADC 100 of FIG. 1 described below, one or more of successive residue stages 125₄ through 125₉ of TDC component 120 includes multiple trim circuits that may be individually selected in calibration and in normal operation based upon the bit output results from previous residue stages 125 in the pipeline. Multi-stage trim select logic 145 is provided in ADC 100 to select the appropriate null delay thresholds from successive residue stages 125₄ through 125₉ of TDC component 120.

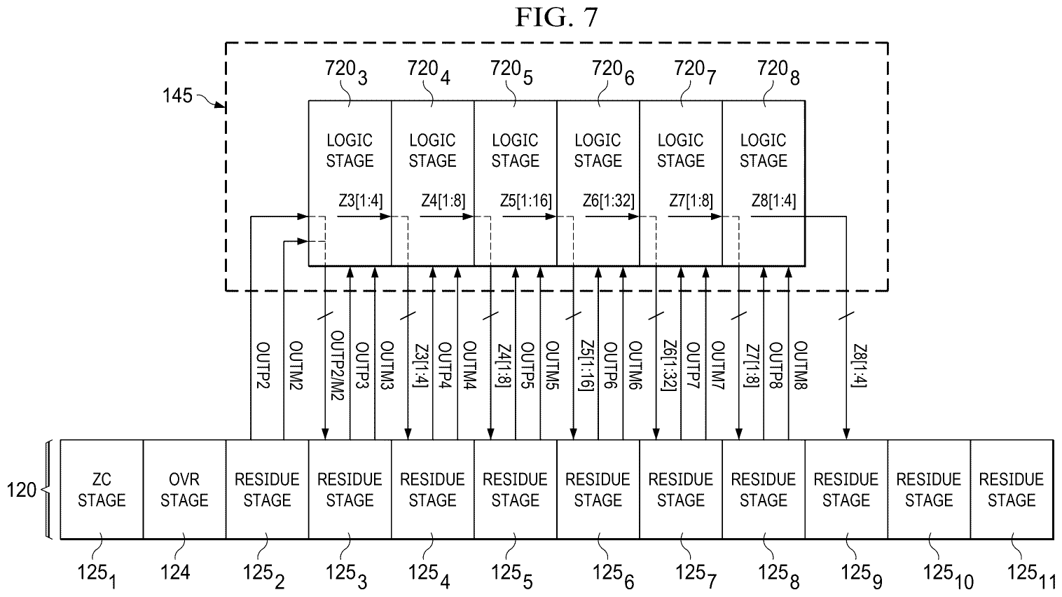

FIG. 7 illustrates an example architecture of multi-stage trim select logic 145 in combination with the various stages of TDC component 120. In this example, TDC component 120 includes zero-crossing stage 125₁, overvoltage stage 124, and residue stages 125₂ through 125₁₁. Trim select logic 145 includes logic stages 720₃, 720₄, 720₅, 720₆, 720₇, and 720₈.

In the block diagram of FIG. 7, logic stage 720₃ has inputs coupled to intermediate outputs OUTP2, OUTM2, and outputs forwarding the logic levels of intermediate outputs OUTP2, OUTM2 to trim circuits 620, 622, 630, 632 respectively, of residue stage 125₃ as shown in FIGS. 5 and 6. Logic stage 7203 also has inputs coupled to intermediate outputs OUTP3, OUTM3 from residue stage 125₃, and outputs coupled to select lines Z3[1:4].

Select lines Z3[1:4] are coupled to inputs of the next logic stage 720₄ in select logic 145, and to residue stage 125₄. Logic stage 720₄ also has inputs coupled to intermediate outputs OUTP4, OUTM3 from residue stage 125₃, and outputs coupled to select lines Z4[1:8]. Select lines Z4[1:8] are coupled to inputs of the next logic stage 720₅ in select logic 145, and to residue stage 125₅. Logic stage 720₅ also has inputs coupled to intermediate outputs OUTP5, OUTM5 from residue stage 125₅, and outputs coupled to select lines Z5[1:16]. Select lines Z5[1:16] are coupled to inputs of the next logic stage 720₆ in select logic 145, and to residue stage 125₆. Logic stage 720₆ also has inputs coupled to intermediate outputs OUTP6, OUTM6 from residue stage 125₆, and outputs coupled to select lines Z6[1:32]. Select lines Z6[1:32] are coupled to inputs of the next logic stage 720₇ in select logic 145, and to residue stage 125₇. Logic stage 720₇ also has inputs coupled to intermediate outputs OUTP7, OUTM7 from residue stage 125₇, and outputs coupled to select lines Z7[1:8].

In this example, select logic stage 720₇ has outputs coupled to only eight select lines Z7[1:8] to residue stage 125₈ and select logic stage 720₈. Similarly, select logic stage 720₈ has outputs coupled to only four select lines Z8[1:4] to residue stage 125₉. As described below,, the benefit of individually calibrating the null delay threshold for each of these smaller sub-ranges diminishes, enabling the calibration of these later, less significant, residue stages 125 in the sequence to be simplified in this manner. As shown in FIG. 7, calibration at residue stages 125₁₀ and 125₁₁ may be implemented in the manner shown for residue stage 125₂ in FIG. 2, or alternatively without trim circuits (e.g., at the last residue stage 125₁₁ in TDC component 120).

Select logic 145 may be implemented in a logic circuit block separate from residue stages 125 (e.g., as part of digital circuitry 140, as suggested by FIG. 7). Alternatively, select logic 145 may be distributed within TDC component 120, for example with each logic stage 720ᵢ implemented within its corresponding residue stage 125ⱼ.

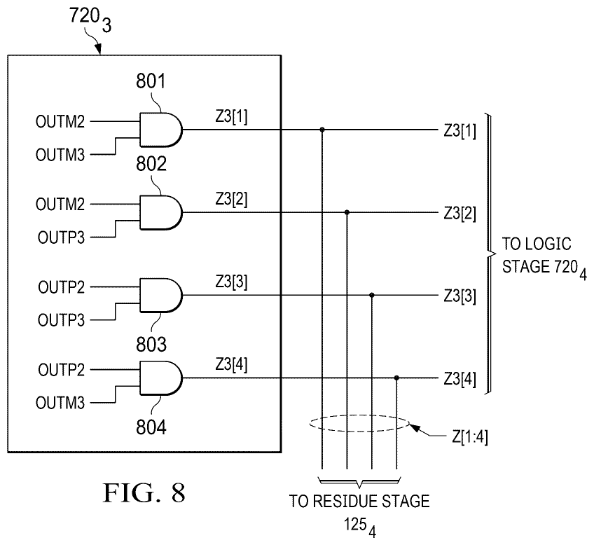

FIG. 8 illustrates an example of logic stage 720₃. Logic stage 720₃ includes logic gates 801, 802, 803, 804. In this example, logic gates 801, 802, 803, 804 are configured as AND logic gates. More particularly, according to the logic convention for this example in which a high-to-low transition from a given residue stage 125ⱼ at its intermediate output OUTMi while holding intermediate output OUTPi high corresponds to bit output Di=1 and a high-to-low transition at its intermediate output OUTPi while holding intermediate output OUTMi high corresponds to bit output Di=0, logic gates 801, 802, 803, 804 are AND gates in a negative logic sense (outputting a “0” in response to a “0” at both inputs, and outputting a “1” otherwise).

Logic gate 801 has one input coupled to intermediate output OUTM2, another input coupled to intermediate output OUTM3, and an output coupled to select line Z3[1]. Logic gate 802 has one input coupled to intermediate output OUTM2, another input coupled to intermediate output OUTP3, and an output coupled to select line Z3[2]. Logic gate 803 has one input coupled to intermediate output OUTP2, another input coupled to intermediate output OUTP3, and an output coupled to select line Z3[3]. Logic gate 804 has one input coupled to intermediate output OUTP2, another input coupled to intermediate output OUTM3, and an output coupled to select line Z3[4]. In this example in which logic gates 801, 802, 803, 804 are AND gates, only one of select lines Z3[1:4] is driven to a high logic level in response to the bit outputs D2, D3 communicated on intermediate outputs OUTP2, OUTM2, OUTP3, OUTM3. Select lines Z3[1:4] are forwarded to inputs of the next logic stage 720₄ in select logic 145, and to residue stage 125₄.

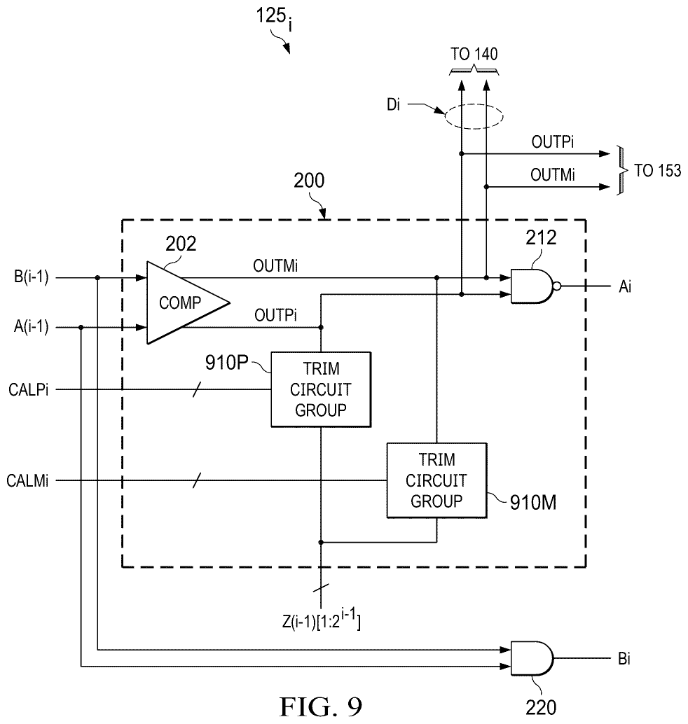

FIG. 9 illustrates an example construction of a residue stage 125ⱼ, as representative of one or more of residue stages 125₄, 125₅, 125₆, 125₇. The same reference numbers are used in FIG. 9 to illustrate those features in residue stage 125ⱼ that are also present in the examples described above relative to FIGS. 2 and 5. As such, residue stage 125ⱼ includes delay comparator 200 and logic gate 220. Delay comparator 200 includes comparator 202 and logic gate 212. Logic gate 212 in this example a NAND gate in this example. Logic gate 220 in this example is an AND gate in this example. Residue stage 125ⱼ also includes trim circuit groups 910P and 910M.

In the case of residue stage 125ᵢ, comparator 202 in delay comparator 200 has inputs coupled to residue signal lines A(i−1) and B(i−1) from a previous residue stage 125ᵢ₋₁, and has intermediate outputs OUTPi, OUTMi. Logic gate 212 has inputs coupled to intermediate outputs OUTPi, OUTMi, and an output coupled to residue signal line Ai. Logic gate 220 has inputs coupled to residue signal lines A(i−1) and B(i−1), and an output coupled to residue signal line Bi. Residue signal lines Ai, Bi are coupled to inputs of a next residue stage 125ⱼ₊₁ in the pipelined sequence of TDC component 120.

Trim circuit group 910P is coupled to intermediate output OUTPi and trim circuit group 910M is coupled to intermediate output OUTMi. Trim circuit group 910P has inputs coupled to calibration signal lines CALPi from outputs of calibration logic 132, and inputs coupled to select lines Z(i−1)[1:2ⁱ⁻¹] from a logic stage 720ᵢ₋₁. Similarly, trim circuit group 910M has one or more inputs coupled to calibration signal lines CALMi from outputs of calibration logic 132, and inputs coupled to select lines Z(i−1)[1:2ⁱ⁻¹] from select logic stage 720ᵢ₋₁.

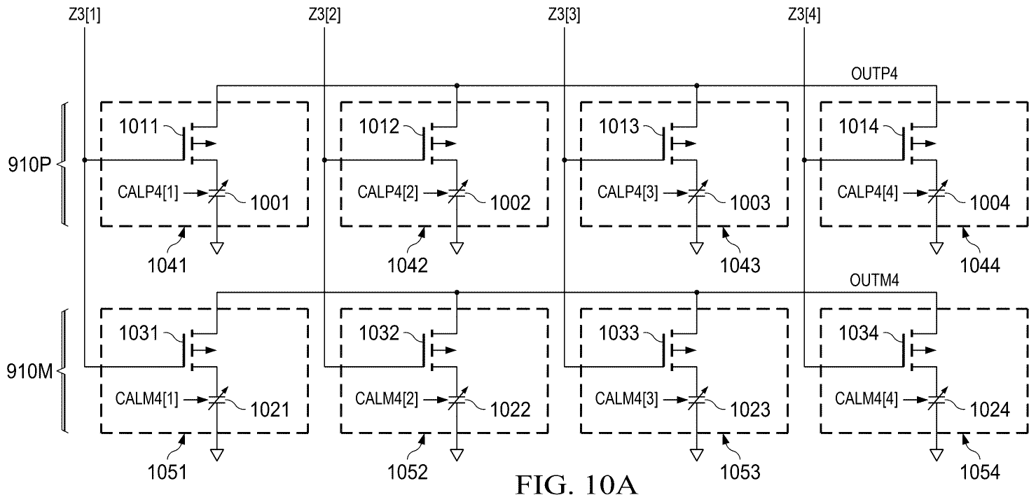

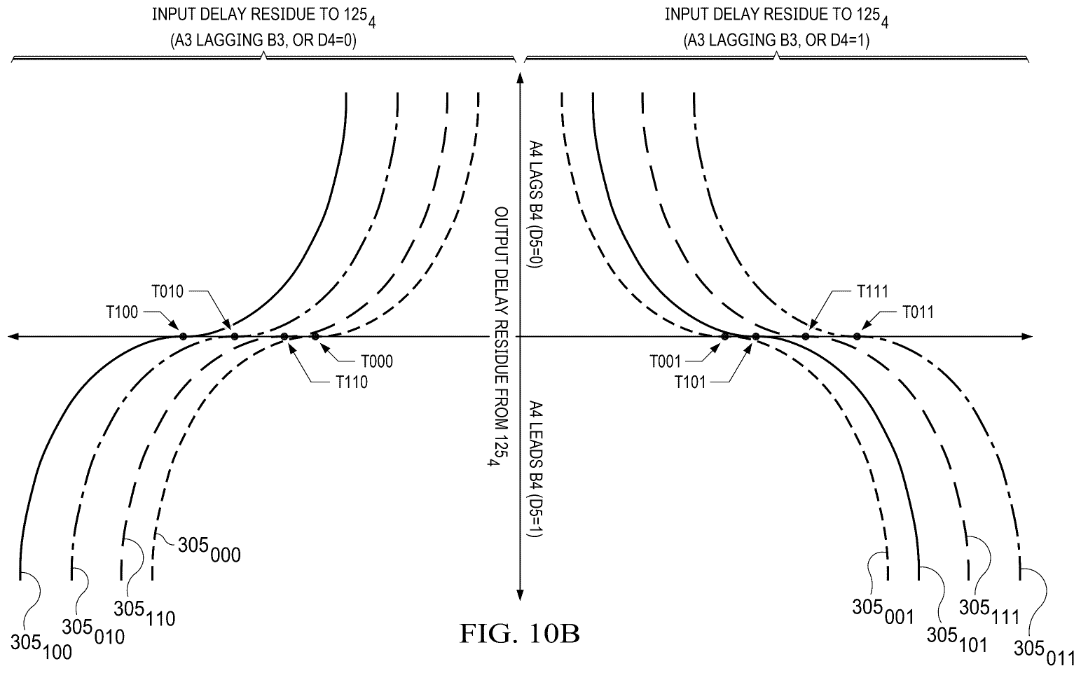

FIG. 10A illustrates simplified examples of trim circuit groups 910P, 910M for the case of residue stage 125₄. Trim circuit group 910P as shown in FIG. 10A includes trim circuits 1041, 1042, 1043, 1044. Trim circuit 1041 includes variable capacitor 1001 and PMOS transistor 1011. Trim circuit 1042 includes variable capacitor 1002 and PMOS transistor 1012. Trim circuit 1043 includes variable capacitor 1003 and PMOS transistor 1013. Trim circuit 1044 includes variable capacitor 1004 and PMOS transistor 1014. Trim circuit group 910M includes trim circuits 1051, 1052, 1053, 1054. Trim circuit 1051 includes variable capacitor 1021 and PMOS transistor 1031. Trim circuit 1052 includes variable capacitor 1022 and PMOS transistor 1032. Trim circuit 1053 includes variable capacitor 1023 and PMOS transistor 1033. Trim circuit 1054 includes variable capacitor 1024 and PMOS transistor 1034. PMOS transistors 1011, 1012, 1013, 1014, 1031, 1032, 1033, and 1034 serve as switches or switching devices in this example, and as such may alternatively be implemented as NMOS transistors, or another type of transistor, pass gate, or other switching device. Variable capacitors 1001, 1002, 1003, 1004, 1021, 1022, 1023, and 1024 may be implemented as switched-capacitor arrays, or in other arrangements of variable capacitors.

In trim circuit 1041, variable capacitor 1001 has one terminal coupled to a common terminal (e.g., circuit ground) and another terminal coupled to a terminal (e.g., a drain) of PMOS transistor 1011. PMOS transistor 1011 has another terminal (e.g., a source) coupled to intermediate output OUTP4 and a control terminal (e.g., a gate) coupled to select line Z3[1] from logic stage 720₃. In trim circuit 1042, variable capacitor 1002 has one terminal coupled to the common terminal and another terminal coupled to a drain of PMOS transistor 1012, which in turn has a source coupled to intermediate output OUTP4 and a gate coupled to select line Z3[2]. In trim circuit 1043, variable capacitor 1003 has one terminal coupled to the common terminal and another terminal coupled to a drain of PMOS transistor 1013, which in turn has a source coupled to intermediate output OUTP4 and a gate coupled to select line Z3[3]. Variable capacitor 1004 in trim circuit 1044 has one terminal coupled to the common terminal and another terminal coupled to a drain of PMOS transistor 1014, which in turn has a source coupled to intermediate output OUTP4 and a gate coupled to select line Z3[4].

Trim circuit 1051 includes variable capacitor 1021 with one terminal coupled to a common terminal (e.g., circuit ground) and another terminal coupled to a drain of PMOS transistor 1031. PMOS transistor 1031 has a source coupled to intermediate output OUTM4 and a gate coupled to select line Z3[1]. In trim circuit 1052, variable capacitor 1022 has one terminal coupled to the common terminal and another terminal coupled to a drain of switch 1032, which in turn has a source coupled to intermediate output OUTM4 and a gate coupled to select line Z3[2]. In trim circuit 1053, variable capacitor 1023 has one terminal coupled to the common terminal and another terminal coupled to a drain of PMOS transistor 1033, which in turn has a source coupled to intermediate output OUTM4 and a gate coupled to select line Z3[3]. Variable capacitor 1024 in trim circuit 1054 has one terminal coupled to the common terminal and another terminal coupled to a drain of switch 1034, which in turn has a source coupled to intermediate output OUTM4 and a gate coupled to select line Z3[4].

While not shown in FIG. 10A for the sake of clarity, reset switches (e.g., such as PMOS transistors 602, 606, 612, 616 of FIG. 6) may be provided in parallel with PMOS transistors 1011, 1012, 1013, 1014, 1031, 1032, 1033, and 1034. Such switches enable the charging of corresponding variable capacitors 1001, 1002, 1003, 1004, 1021, 1022, 1023, and 1024 to a selected voltage (e.g., power supply voltage VDD) in preparation for each conversion operation by ADC 100, ensuring a constant initial condition for each sample conversion.

In operation, the capacitance applied by one of trim circuits 1041, 1042, 1043, 1044, 1051, 1052, 1053, 1054 in residue stage 125₄ in a given conversion is selected by select logic stage 720₄ based on the bit outputs D2 and D3 in combination with the bit output result indicated by intermediate outputs OUTP4, OUTM4 of residue stage 125₄ itself. For example, if bit outputs D2=1 and D3=1 (e.g., intermediate outputs OUTM2 and OUTM3 are both at a low logic level), NOR gate 801 drives select line Z3[1] to a low logic level, and select lines Z3[2:4] are all driven high. PMOS transistors 1011 and 1031 in trim circuits 1041 and 1051, respectively, are turned on by select line Z3[1] in this event, coupling variable capacitors 1001 and 1021 to intermediate outputs OUTP4 and OUTPM, respectively. The delay of the transition at the output of logic gate 212 in delay comparator 200 is affected by the capacitance of variable capacitor 1001 if a high-to-low transition is driven at intermediate output OUTP4, and by the capacitance of variable capacitor 1021 if a high-to-low transition is driven at intermediate output OUTM4.

FIG. 10B illustrates an example of the non-linear relationships of output delay residue of residue stage 125₄ in response to the input delay residue received at delay signal lines A3, B3. In this example, the eight trim circuits 1041, 1042, 1043, 1044, 1051, 1052, 1053, 1054 of residue stage 125₄ define eight such non-linear relationships, as shown in FIG. 10B by eight curves 305₀₀₀, 305₀₀₁, 305₀₁₀, 305₀₁₁, 305₁₀₀, 305₁₀₁, 305₁₁₀, and 305₁₁₁ (generically or collectively referred to as curve or curves 305). Each curve 305 of FIG. 10B has a null delay threshold corresponding to the value of input delay residue at delay residue lines A3, B3 that results in zero output delay residue at output delay residue lines A4, B4. Specifically, curves 305₀₀₀, 305₀₀₁, 305₀₁₀, 305₀₁₁, 305₁₀₀, 305₁₀₁, 305₁₁₀, and 305₁₁₁ have null delay thresholds T₀₀₀, T₀₀₁, T₀₁₀, T₀₁₁, T₁₀₀, T₁₀₁, T₁₁₀, and T₁₁₁, respectively (said null delay thresholds generically or collectively referred to as null delay threshold or thresholds T). These null delay thresholds T establish the input delay residue values used by residue stage 125₄ in determining the polarity of its output delay residue, namely whether the transition at residue signal line A4 leads that at residue signal line B4, or vice versa. In this example, the selection of which one of null delay thresholds T is applied by residue stage 125₄ for a given analog input voltage is made in response to the bit outputs D2 and D3 from residue stages 125₂, 125₃, respectively, in combination with the polarity of the input delay residue received by residue stage 125₄ (e.g., the bit output of residue stage 125₄ itself).

In this example, the four curves 305₀₀₁, 305₀₁₁, 305₁₀₁, 305₁₁₁ on the right-hand side of FIG. 10B correspond to the case in which the signal at input residue signal line A3 leads that at input residue signal line B4 (e.g., bit output D4=1, corresponding to intermediate output OUTM4 being driven low by delay comparator 200). These curves 305₀₀₁, 305₀₀₁, 305₁₀₁, 305₁₁₁ establish null delay thresholds T₀₀₁, T₀₁₁, T₁₀₁, T₁₁₁, respectively, at varying positions along the horizontal axis based on the capacitances of variable capacitors 1021, 1022, 1023, 1024, respectively, in trim circuits 1051, 1052, 1053, 1054. Conversely, curves 305₀₀₀, 305₀₁₀, 305₁₀₀, 305₁₁₀ on the left-hand side of FIG. 10B correspond to the case in which the signal at input residue delay line A3 lags that at input residue delay line B4 (e.g., bit output D4=0, corresponding to intermediate output OUTP4 being driven low by delay comparator 200). These curves 305₀₀₀, 305₀₀₀, 305₁₀₀, 305₁₁₀establish null delay thresholds T₀₀₀, T₀₁₀, T₁₀₀, T₁₁₀, respectively, at varying positions along the horizontal axis based on the capacitances of variable capacitors 1001, 1002, 1003, 1004, respectively, in trim circuits 1041, 1042, 1043, 1044.

Accordingly, residue stage 125₄ in this example has eight independently controlled null delay thresholds T₀₀₀, T₀₀₁, T₀₁₀, T₀₁₁, T₁₀₀, T₁₀₁, T₁₁₀, and T₁₁₁,and Tin available for generating its output delay residue at delay residue lines A4, B4 in response to an input delay residue. These null delay thresholds are independently controlled in the sense that each is individually adjustable, for example by calibration circuitry 150, independently of the other null delay thresholds of residue stage 125₄.

Selection of the particular curve 305, and thus the particular null delay threshold value T, is based on the bit outputs D2 and D3 from residue stages 125₂ and 125₃, respectively, in combination with the polarity of the input delay residue received by residue stage 125₄, which is the bit output result indicated by intermediate outputs OUTP4, OUTM4 of residue stage 125₄ itself. In this example, this selection is made by select logic stage 720₄ selecting one of four trim circuits in each of trim circuit groups 910P, 910M, in combination with residue stage 125₄ selecting the one of trim circuit groups 910P, 910M based on whether the signal at input residue signal line A3 leads or lags that at residue signal line B3.

Accordingly, the bit output results from residue stages 125₂ and 125₃, along with the bit output result from residue stage 125₄ itself, determines the selection of the one of variable capacitors 1001, 1002, 1003, 1004, 1021, 1022, 1023, and 1024 that determines the response of residue stage 125₄ as follows:

TABLE 2

| | | | | Variable | |
|---|---|---|---|---|---|
| | | | | capacitor | |
| Bit | Bit | Select | Bit | acting in | Delay |
| output | output | line | output | residue stage | threshold |
| D2 | D3 | asserted | D4 | 125₄ | calibrated |
| 0 | 0 | Z3[3] | 0 | 1003 | T₀₀₀; P |
| 0 | 1 | Z3[4] | 0 | 1004 | T₀₁₀; N |
| 1 | 0 | Z3[2] | 0 | 1002 | T₁₀₀; S |
| 1 | 1 | Z3[1] | 0 | 1001 | T₁₁₀; T |
| 0 | 0 | Z3[3] | 1 | 1023 | T₀₀₁; Q |
| 0 | 1 | Z3[4] | 1 | 1024 | T₀₁₁; M |
| 1 | 0 | Z3[2] | 1 | 1022 | T₁₀₁; R |
| 1 | 1 | Z3[1] | 1 | 1021 | T₁₁₁; U |

As evident from Table 2, the arrangement of select logic stage 720₃ and trim circuits 1041, 1042, 1043, 1044, 1051, 1052, 1053, 1054 in residue stage 125₄ enable the separate and independent calibration and adjustment of the null delay thresholds in each of the ⅛ FS sub-ranges (FIG. 4).

As mentioned above, the next residue stage 125₅ generates an output delay residue for a range of input voltage V that is one-half that evaluated by residue stage 125₄. Accordingly, the number of independently controlled null delay thresholds available for calibration at residue stage 125₅ is sixteen, twice that of the eight null delay thresholds calibrated at residue stage 125₄ as evident from Table 2. FIG. 7 according to this example shows select logic stage 720₄ having inputs receiving select lines Z3[1:4] from select logic stage 720₃ and also the intermediate outputs OUTP4, OUTM4 from residue stage 125₄. Select logic stage 720₄ has outputs coupled to select lines Z4[1:8], used by residue stage 125₅ in its selection of the appropriate variable capacitor in its trim circuit groups 910P, 910M.

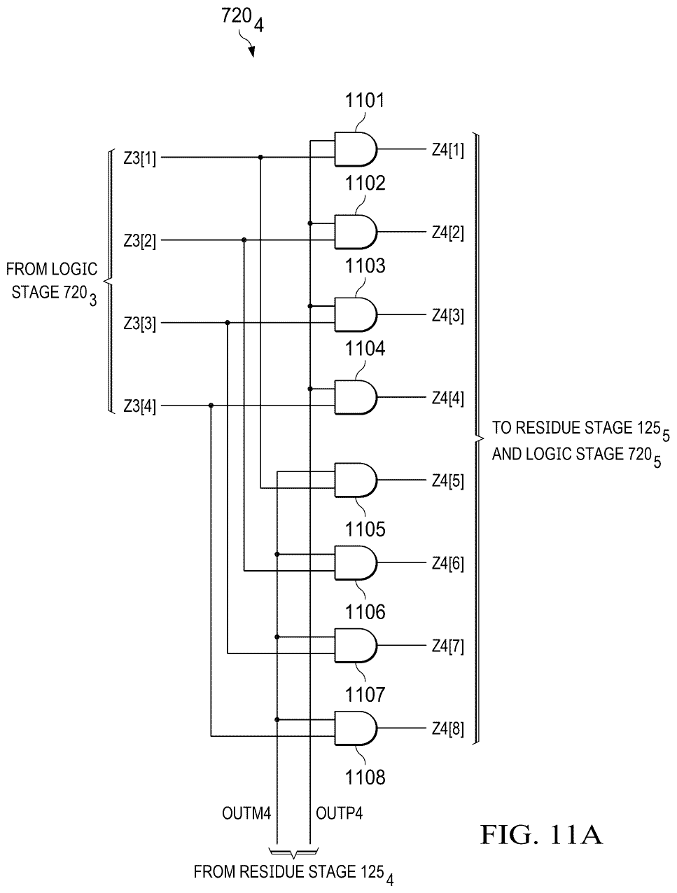

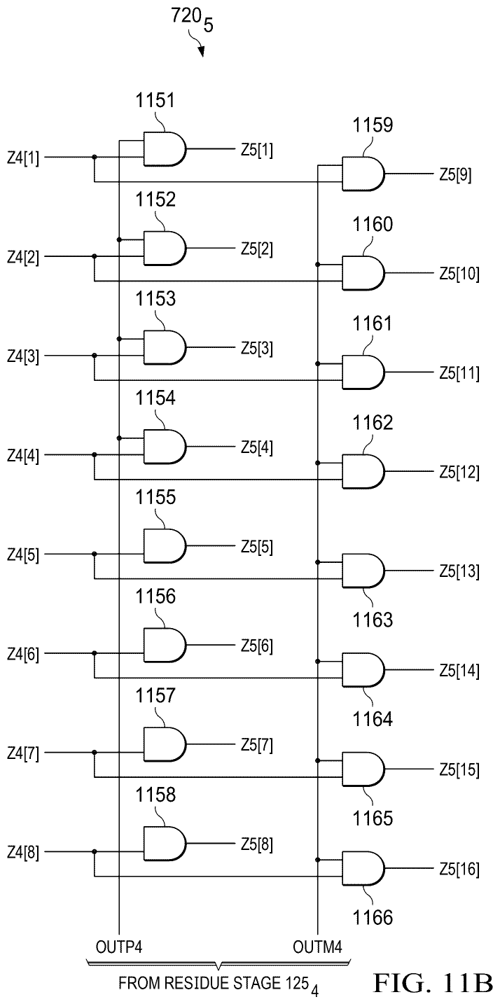

FIG. 11A illustrates the construction of select logic stage 720₄ according to an example. Logic stage 720₄ includes logic gates 1101, 1102, 1103, 1104, 1105, 1106, 1107, and 1108. In this example, logic gates 1101, 1102, 1103, 1104, 1105, 1106, 1107, and 1108 are configured as AND logic gates. According to the same logic convention as described above relative to select logic stage 720₃, logic gates 1101, 1102, 1103, 1104, 1105, 1106, 1107, and 1108 are AND gates in a negative logic sense (outputting a “0” in response to a “0” at both inputs, and outputting a “1” otherwise).

Logic gate 1101 has one input coupled to select line Z3[1], another input coupled to intermediate output OUTP4 of residue stage 125₄, and an output coupled to select line Z4[1]. Logic gate 1102 has one input coupled to select line Z3[2], another input coupled to intermediate output OUTP4, and an output coupled to select line Z4[2]. Logic gate 1102 has one input coupled to select line Z3[2], another input coupled to intermediate output OUTP4, and an output coupled to select line Z4[3]. Logic gate 1104 has one input coupled to select line Z3[4], another input coupled to intermediate output OUTP4, and an output coupled to select line Z4[4]. Logic gate 1105 has one input coupled to select line Z3[1], another input coupled to intermediate output OUTM4 of residue stage 125₄, and an output coupled to select line Z4[5]. Logic gate 1106 has one input coupled to select line Z3[2], another input coupled to intermediate output OUTM4, and an output coupled to select line Z4[6]. Logic gate 1107 has one input coupled to select line Z3[2], another input coupled to intermediate output OUTM4, and an output coupled to select line Z4[7]. Logic gate 1108 has one input coupled to select line Z3[4], another input coupled to intermediate output OUTM4, and an output coupled to select line Z4[8].

According to this arrangement, select logic stage 720₄ generates signals on eight select lines Z4[1:8] that are forwarded to residue stage 125₅ and to select logic stage 120₅. The states at select lines Z4[1:8] are determined by the states of bit outputs D2 and D3, communicated by way of select lines Z3[1:4], and the state of bit output D4, communicated directly by intermediate outputs OUTP4, OUTM4. In this example, only one of select lines Z4[1:8] is driven to a low logic level by its corresponding logic gate 1101 through 1108; the remainder of select lines Z4[1:8] remain at a high logic level.

The use of select lines Z3[1:4] as inputs to logic gates 1101 through 1108 (as opposed to, e.g., bit outputs D2 and D3) enables select logic stage 720₄ to implement its select logic in a single “layer” of logic, with a propagation delay of only a single logic gate in generating the signals at select lines Z4[1:8]. This single propagation delay of select logic stage 720₄ (and similarly each of the stages of trim select logic 145) is on the same order as the stage delay of residue stages 125. Accordingly, the logic function of select logic stage 720₄ can be asynchronous, resetting when the comparators of residue stages 125 reset between conversions, and switching along with the switching of intermediate outputs along the pipeline of TDC component 120.

As described above, residue stage 125₅ generates an output delay residue for a range of input voltage V that is one-half that evaluated by residue stage 125₄, and thus defines sixteen null delay thresholds, twice the eight null delay thresholds defined by residue stage 125₄. Following the example construction of FIG. 9, trim circuit groups 910P and 910M of residue stage 125₄ each include eight trim circuits, and thus eight variable capacitors, selectable by a low logic level (e.g., to turn on an associated PMOS transistor as in FIG. 10A) on an associated select line Z4[1:8] from logic stage 720₄. This arrangement of select logic stage 720₄ and trim circuit groups 910P, 910M in residue stage 125₅ enables the separate and independent calibration and adjustment of the null delay thresholds in each of sixteen 1/16 FS sub-ranges.

Referring again to the example of trim select logic 145 of FIG. 7, select logic stage 720₅ has inputs receiving select lines Z3[1:8] from select logic stage 720₄ and receiving the intermediate outputs OUTP5, OUTM5 from residue stage 125₄. Select logic stage 720₅ has outputs coupled to select lines Z5[1:8], used by residue stage 125₆ in its selection of the appropriate trim circuit in each of its trim circuit groups 910P, 910M.

FIG. 11B illustrates the construction of select logic stage 720₅ according to an example. Logic stage 720₅ includes logic gates 1151, 1152, 1153, 1154, 1155, 1156, 1157, 1158, 1159, 1160, 1161, 1162, 1163, 1164, 1165, and 1166 (collectively referred to as logic gates 1151 through 1166). In this example, logic gates 1151 through 1166 are configured as AND logic gates. According to the same logic convention as described above relative to select logic stage 720₅, logic gates 1151 through 1166 are AND gates in a negative logic sense (outputting a “0” in response to a “0” at both inputs, and outputting a “1” otherwise).

Logic gate 1151 has one input coupled to select line Z4[1], another input coupled to intermediate output OUTP5 of residue stage 125₅, and an output coupled to select line Z5[1]. Logic gate 1152 has one input coupled to select line Z4[2], another input coupled to intermediate output OUTP5, and an output coupled to select line Z5[2]. Logic gate 1153 has one input coupled to select line Z4[3], another input coupled to intermediate output OUTP5, and an output coupled to select line Z5[3]. Logic gate 1154 has one input coupled to select line Z4[4], another input coupled to intermediate output OUTP5, and an output coupled to select line Z5[4]. Logic gate 1155 has one input coupled to select line Z4[5], another input coupled to intermediate output OUTP5, and an output coupled to select line Z5[5]. Logic gate 1156 has one input coupled to select line Z4[6], another input coupled to intermediate output OUTP5, and an output coupled to select line Z5[6]. Logic gate 1157 has one input coupled to select line Z4[7], another input coupled to intermediate output OUTP5, and an output coupled to select line Z5[7]. Logic gate 1158 has one input coupled to select line Z4[2], another input coupled to intermediate output OUTP5, and an output coupled to select line Z5[8].

Logic gate 1159 has one input coupled to select line ZA[1], another input coupled to intermediate output OUTM5 of residue stage 125₅, and an output coupled to select line Z5[9]. Logic gate 1160 has one input coupled to select line Z4[2], another input coupled to intermediate output OUTM5, and an output coupled to select line Z5[10]. Logic gate 1161 has one input coupled to select line Z4[3], another input coupled to intermediate output OUTM5, and an output coupled to select line Z5[11]. Logic gate 1162 has one input coupled to select line Z4[4], another input coupled to intermediate output OUTM5, and an output coupled to select line Z5[12]. Logic gate 1163 has one input coupled to select line Z4[5], another input coupled to intermediate output OUTM5, and an output coupled to select line Z5[13]. Logic gate 1164 has one input coupled to select line Z4[6], another input coupled to intermediate output OUTM5, and an output coupled to select line Z5[14]. Logic gate 1165 has one input coupled to select line Z4[7], another input coupled to intermediate output OUTM5, and an output coupled to select line Z5[15]. Logic gate 1166 has one input coupled to select line Z4[2], another input coupled to intermediate output OUTP5, and an output coupled to select line Z5[16].

Select logic stage 720₅ generates signals on sixteen select lines Z5[1:16] that are forwarded to residue stage 125₆ and to select logic stage 120₆. The states at select lines Z5[1:16] are determined by the states of bit outputs D2, D3, and D4 as communicated by way of select lines Z4[1:8], and the state of bit output D5, communicated directly by intermediate outputs OUTP5, OUTM5. In this example, only one of select lines Z5[1:16] is driven to a low logic level by its corresponding logic gate 1151 through 1166; the remainder of select lines Z5[1:16] remain at a high logic level.

Similarly, as select logic stage 720₄ described above, logic gates 1151 through 1166 select logic stage 720₅ receive select lines Z4[1:8] as inputs, rather than, e.g., bit outputs D2, D3, and D4 directly. As a result, select logic stage 720₅ can be implemented in a single logic layer, presenting only a single gate propagation delay in its generating of signals at select lines Z5[1:16]. Accordingly, select logic stage 720₄ can also operate asynchronously, resetting when the comparators of residue stages 125 reset between conversions, and switching along with the switching of intermediate outputs along the pipeline of TDC component 120.

The next residue stage 125₆ generates an output delay residue for a range of input voltage V that is one-half that evaluated by residue stage 125₅, and thus defines thirty-two null delay thresholds, twice the sixteen null delay thresholds defined by residue stage 125₅. Following the example construction of FIG. 9, trim circuit groups 910P and 910M of residue stage 125₄ each include sixteen trim circuits, and thus sixteen variable capacitors, selectable by a low logic level (e.g., to turn on an associated PMOS transistor as in FIG. 10A) on an associated select line Z5[1:16] from logic stage 720₄. This arrangement of select logic stage 720₅ and trim circuit groups 910P, 910M in residue stage 125₆ enable the separate and independent calibration and adjustment of the null delay thresholds in each of thirty-two 1/32 FS sub-ranges.

The construction of select logic stages 720₆, 720₇, 720₈ follows that of select logic stages 720₃, 720₄, 720₅ described above, differing only in the number of logic gates and thus the number of select lines output by those stages. Referring to FIG. 7, select logic stage 720₆ has inputs receiving select lines Z5[1:16] from select logic stage 720₅ and receiving the intermediate outputs OUTP6, OUTM6 from residue stage 125₄. Select logic stage 720₆ has outputs coupled to select lines Z6[1:32], used by residue stage 125₇ in combination with its intermediate outputs OUTP7, OUTM7 to select one of sixty-four variable capacitors in its trim circuit groups 910P, 910M, in similar fashion as described above for earlier residue stages 125.

As described above, later residue stages 125 evaluate delay residue over sub-ranges of ever-decreasing width to output less significant bits of digital output word DOUT. In some implementations, the benefit of individually calibrating the null delay threshold for each of these smaller sub-ranges diminishes, eventually to a point at which the null delay threshold variation is less than one LSB of ADC 100. As such, the calibration of these later, less significant, residue stages 125 can be simplified, for example by using one calibration for multiple null delay thresholds (multiple sub-ranges). In the example of trim select logic 145 and TDC component 120 of FIG. 7, for example, select logic stage 720₇ includes only eight logic gates, and thus outputs only eight select lines Z7[1:8] to residue stage 125₈ and select logic stage 720₈. Similarly, select logic stage 720₈ includes only four logic gates, outputting only four select lines Z8[1:4] to residue stage 125₉. Calibration at residue stages 125₁₀ and 125₁₁ may be implemented in the manner shown for residue stage 125₂ in FIG. 2, or alternatively without trim circuits (e.g., at the last residue stage 125₁₁ in TDC component 120).

According to the described examples, ADC 100 enables calibration in its TDC component 120, with such calibration performed separately and independently for each of multiple null delay thresholds along the full input voltage scale. This separate and independent calibration and correction for non-linearity in the delay-domain analog-to-digital conversion process provides improved integral-non-linearity performance. For example, in prior art calibration approaches that do not provide for such independent calibration, the calibration at one null delay threshold in one sub-range also affects other null delay thresholds in other sub-ranges. A more granular calibration within the input voltage range, and thus better optimization of conversion error, is provided in ADC 100 according to the described examples, improving the linearity and accuracy of delay-domain ADCs. This improvement can allow a high sample rate precision delay-domain ADC without a look-up table (LUT) for linearization of the digital output, thus reducing the latency of the ADC along with the improvement in integral non-linearity.

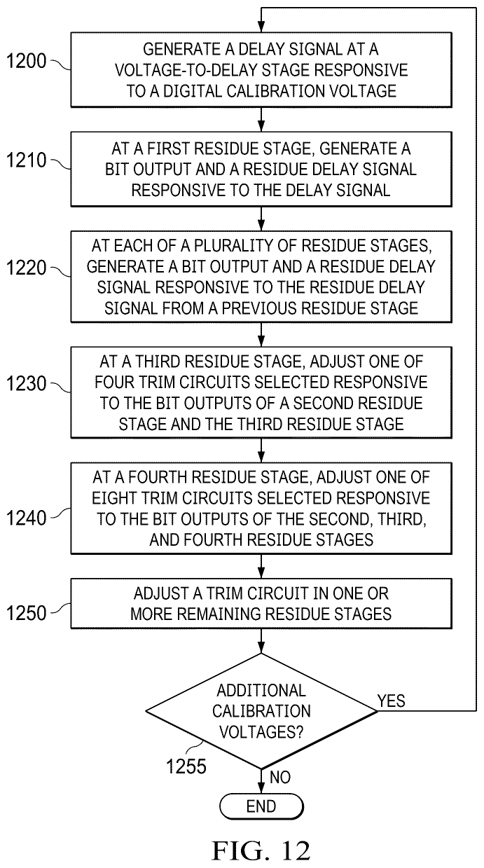

FIG. 12 illustrates an example method of calibrating ADC 100 of FIG. 1. This calibration may be performed at one or more events such as power-up of ADC 100, periodically during its operation, and in response to events during operation (e.g., upon detection of an error condition, in response to an interrupt, etc.). The above-incorporated U.S. Patent Application Publication No. US 2024/0171190 Al describes a generalized calibration method within which the particular operations described below may be implemented.

Calibration according to this example begins in process block 1200 with the initiation by digital circuitry 240 of a calibration operation. For example, calibration logic 132 outputs a digital word representing a calibration voltage to DAC 134 on signal line(s) DAC_IN, and outputs a select signal to the control input of input multiplexer 136 via signal line CAL_SEL. In response, input multiplexer 136 selects calibration voltage VDAC from DAC 134 for application to V2D component 110 as analog voltage V. In process block 1200, V2D component 110 generates a delay-domain signal corresponding to calibration voltage VDAC, and thus corresponding to the digital calibration voltage word from calibration logic 132, for example in the form of a relative delay between logic level transitions on delay signal lines A0, B0 corresponding to the calibration voltage VDAC.

In process block 1210, a first residue stage in TDC component 120 generates a bit output and a residue delay signal in response to the delay signal generated in process block 1200. For the example of ADC 100 of FIG. 1, process block 1210 is performed by zero-crossing stage 125₁ generating a bit output DI corresponding to a sign bit of the digital output word DOUT, and a residue delay signal at residue signal lines Al, B1. Also in process block 1210, for the example of ADC 100, optional over-range stage 124 applies gain to the residue delay signal generated by zero-crossing stage 125₁ to produce a modified residue delay signal at residue signal lines A1′, B1′.

In process block 1220, residue stages 125₂ through 125ⱼ of TDC component 120 each generate a bit output and a residue delay signal in a pipelined fashion, each residue stage 125 generating its outputs in response to the residue delay signal received from the previous stage. Digital circuitry 140 outputs a digital word DOUT in response to these bit outputs generated in process block 1220. This digital word DOUT is forwarded to calibration logic 132 in ADC 100 in this example.

In process block 1230, calibration logic 132 adjusts one of four trim circuits in third residue stage 125₃ selected in response to the values of bit outputs D2 and D3, to adjust the null delay thresholds to be applied by a next residue stage 125₄. In the example of ADC 100 and referring to FIGS. 4, 5, 6A, and 6B, process block 1230 includes calibration logic 132 issuing digital calibration words on calibration signal lines CALP3₁, CALP3₀, CALM3₁, or CALM3₀ to adjust the one of variable capacitors 605, 607, 615, 617 corresponding to the current values of bit outputs D2, D3 indicated at intermediate outputs OUTP2, OUTM2, OUTP3, OUTP3. The adjustment of the selected variable capacitor calibrates the corresponding one of null delay thresholds A, B, C, D used by residue stage 125₄ in determining bit output D4.

In process block 1240, calibration logic 132 adjusts one of eight trim circuits in fourth residue stage 125₄ selected in response to the values of bit outputs D2, D3, and D4, to adjust the null delay thresholds to be applied by a next residue stage 125₅. In the example of ADC 100 and referring to FIGS. 4 and 8 through 10, process block 1240 includes calibration logic 132 issuing digital calibration words to adjust the one of the variable capacitors in trim circuit groups 910P, 910M corresponding to the current values of bit outputs D2 and D3 indicated at select lines Z1[1:4] from select logic stage 720₃ in combination with the current value of bit output D4 at intermediate outputs OUTP4, OUTM4. The adjustment of the selected variable capacitor calibrates the corresponding one of null delay thresholds M, N, P, Q, R, S, T, U used by residue stage 125₅ in determining bit output D5.

In process block 1250, a trim circuit in one or more additional residue stages 125 later in the sequence of TDC component 120 may be adjusted in a similar manner as in process block 1240, with that trim circuit selected based on the bit outputs of two or more previous residue stages.

Following process block 1250, decision 125₅ is executed by calibration logic 132 to determine whether calibration is to be performed for any more calibration voltages. If so (decision 125₅ is “yes”), the method of FIG. 12 is repeated for another calibration voltage beginning with process block 1210. If not (decision 125₅ is “no”), calibration of ADC 100 is complete until calibration is next initiated.

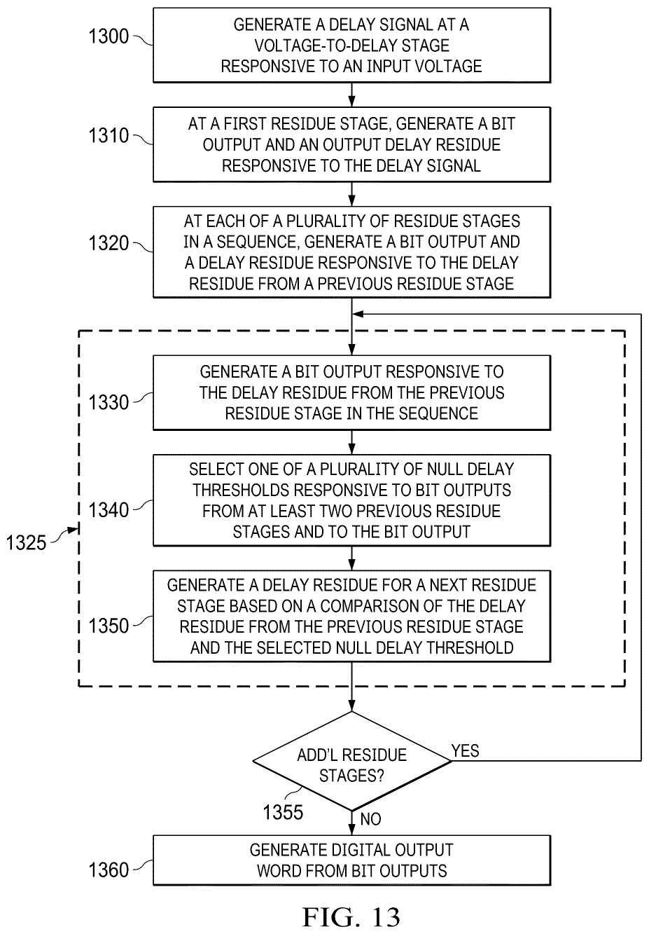

FIG. 13 illustrates a method of operating ADC 100 according to the described examples. In this method of FIG. 13, calibration logic 132 issues a signal on line CAL_SEL causing input multiplexer to select the voltage at input VIN for forwarding to V2D component 110 on line V. In process block 1300, V2D component 110 generates a delay-domain signal in response to an analog voltage received on line V. This delay-domain signal generated in process block 1300 is in the form of a relative delay between logic level transitions on delay signal lines A0, B0 corresponding to the calibration voltage VDAC.

In process block 1310, a first residue stage in TDC component 120 generates a bit output and a residue delay signal in response to the delay signal generated in process block 1300. For the example of ADC 100 of FIG. 1, process block 1310 is performed by zero-crossing stage 125₁ generating a bit output DI corresponding to a sign bit of the digital output word DOUT, and a residue delay signal at residue signal lines A1, B1. Also in process block 1310, for the example of ADC 100, optional overvoltage stage 125 applies gain to the delay residue signal generated by zero-crossing stage 125₁ to produce a modified delay residue signal at residue signal lines A1′, B1′.

In process block 1320, two or more residue stages 125 of TDC component 120 each generate a bit output and a residue delay signal in a pipelined fashion, each residue stage 125 generating its outputs in response to the residue delay signal received from the previous stage.

Process block 1325 is performed at one or more residue stages 125 later in sequence than the two or more residue stages 125 operating in process block 1320 for a given input voltage. As described above, process block 1325 may be performed at residue stage 125₄ and one or more later residue stages 125 in TDC component 120. The following description of process block 1325 refers to residue stage 125₄ by way of example.

Process block 1325 includes process block 1330, in which residue stage 125₄ generates a bit output (e.g., bit output D4) in response to the output delay residue from previous residue stage 125₃ (also referred to as the input delay residue to residue stage 125₄ ).

As described above relative to FIG. 10B, residue stage 125₄ has multiple available null delay thresholds, one of which may be used in generating an output delay residue to the next residue stage 125 in TDC component 120. In process block 1340, one of these multiple null delay thresholds is selected, based on the bit outputs from at least two previous residue stages and to the bit output from residue stage 125₄ itself as generated in process block 1330. In ADC 100 according to the example described above, process block 1340 is performed by select logic 720 issuing a select signal on one of four select lines Z3[1:4], selecting a trim circuit in each of trim circuit groups 910P, 910M. The bit output D4 from residue stage 125₄ itself, indicated at one of intermediate outputs OUTP4, OUTM4, determines which of the two selected trim circuits determines the selected null delay threshold.

In process block 1350, residue stage 125₄ generates an output delay residue at delay signal lines A4, B4 in response to a comparison of the input delay residue from residue stage 125₃ with the null delay threshold selected in process block 1340. More particularly, the output delay residue generated by residue stage 125₄ has a polarity, indicated by the signal transition at delay signal line A4 leading or lagging that at delay signal line B4, with the residue corresponding to the relative delay between the two signals.

Decision 1355 determines whether one or more additional residue stages 125 remain in the sequence of TDC component 120 for digitizing the input voltage. If so (decision 1355 is “yes”), process block 1325 is repeated by those one or more additional residue stages 125, based on the output delay residue generated by residue stage 125₄ in process block 1350. The number of null delay thresholds available in each of these later residue stages 125 can increase, for example as described above for residue stages 125₅ through 125₇ as shown in FIG. 7, in which case the bit outputs from more than two previous residue stages 125 are used for selecting among the larger number of null delay thresholds. Also as described above, the residue stages 125 generating the least significant bit outputs (e.g., residue stages 125₈ through 125₁₁ of FIG. 7) may have fewer null delay thresholds, or may not select any null delay threshold (as in the case of residue stages 125₁₀ and 125₁₁).

If no additional residue stages 125 remain (decision 1355 is “no”), process block 1360 is performed. In process 1360, digital circuitry 140 outputs a digital word DOUT in response to the bit outputs generated in process blocks 1310, 1320, 1330, for example by the sequence of residue stages 125 in TDC component 120.

The overall process can be repeated by ADC 100 for additional samples or instances of voltage at input VIN.

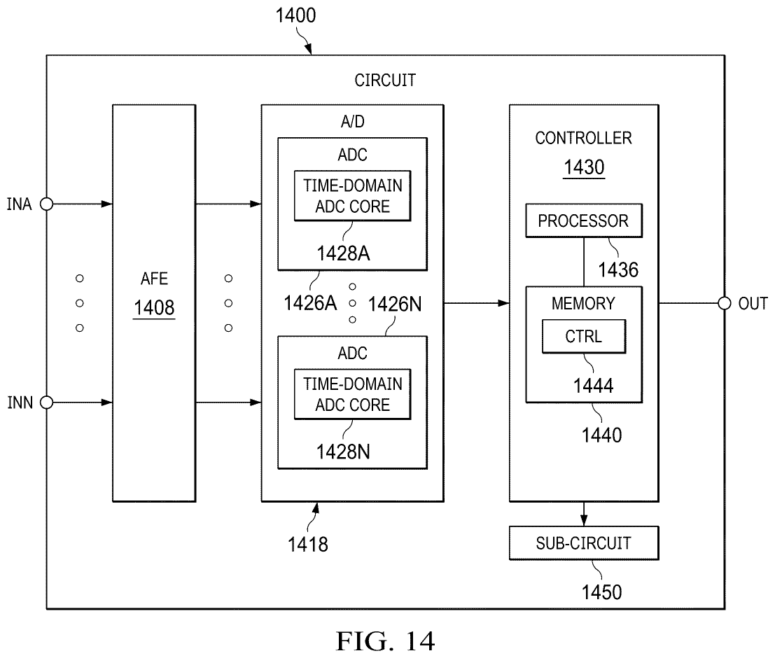

FIG. 14 is a block diagram showing an example circuit 1400 with ADC cores 1428A to 1428N. At least one of the TD ADC cores 1428A to 1428N is an example of the ADC core 100 of FIG. 1. In some examples, circuit 1400 may be an integrated circuit (IC) or multiple ICs. As shown, circuit 1400 has a set of input terminals INA to INN, and an output terminal OUT.

In addition to ADC cores 1428A through 1428N, circuit 1400 includes analog front-end circuitry (AFE) 1408, analog-to-digital (A/D) circuitry 1418, a controller 1430, and a sub-circuit 1450. As shown, the A/D circuitry 1418 includes ADCs 1426A to 1426N. Each of the ADCs 1426A to 1426N includes a respective ADC core 1428A to 1428N, respectively. In some examples, one or more of ADCs 1426A to 1426N are constructed according to ADC 100 described above relative to FIG. 1. In some examples, controller 1430 includes processor 1436 coupled to memory 1440. Memory 1444 may include memory locations storing control instructions 1444 for execution by processor 1436.

AFE circuitry 1408 has inputs coupled to input terminals INA through INN, and outputs coupled to inputs of A/D circuitry 1418. A/D circuitry 1418 has one or more outputs coupled to inputs of controller 1430. Within controller 1430, processor 1436 may be coupled bi-directionally to inputs of memory. Controller 1430 may also have an output coupled to an input of sub-circuit 1450; alternatively, the coupling of controller 1430 and sub-circuit 1450 may be bidirectional.

In some examples, circuit 1400 operates to receive analog input signals at one or more of input terminals INA through INN, for example from a wired cable interface, or from antennas receiving wireless signals. AFE circuitry 1408 filters, amplifies, or otherwise conditions the received analog input signals, and provide the conditioned signals to A/D circuitry 1418. A/D circuitry 1418 operates to digitize (e.g., convert) the conditioned analog signals from AFE circuitry 1408 to digital words using one or more of ADCs 1426A to 1426N, and to provide these digital words to controller 1430 for processing by processor 1436, for example according to executable program instructions (e.g., control instructions 1444) stored in memory 1440. Sub-circuit 1450, if provided, may carry out some action in response to the results of the processing by controller 1430, for example to adjust a voltage, adjust a current, control a switch, control an actuator, control a motor, adjust information on a display, and/or adjust other components in a larger-scale system responsive to the control response.

Examples are described in this specification as implemented into a pipelined delay-domain ADC as such implementation can be advantageous in that context. It is further contemplated that these examples may be beneficially applied in other applications, for example data converters or other delay-domain processing circuits in which calibration compensation of non-linearities may be beneficial. Accordingly, the above description is provided by way of example only, and is not intended to limit the true scope as claimed.

As used herein, the terms “terminal”, “node”, “interconnection” and “pin” are used interchangeably. Unless specifically stated to the contrary, these terms are generally used to mean an interconnection between or a terminus of a device element, a circuit element, an integrated circuit, a device, or other electronics or semiconductor component.

Unless otherwise stated, “about,” “approximately,” or “substantially” preceding a value means +/−10 percent of the stated value. Modifications are possible in the described examples, and other examples are possible within the scope of the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. While, in some examples, certain elements are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

Modifications are possible in the described examples, and other examples are possible, within the scope of the claims.

What is claimed is:

1. An analog-to-digital converter, comprising:
a voltage-to-delay circuit having an input and first and second outputs;
a plurality of residue stages coupled in a sequence, comprising:
a first residue stage, having a bit output and first and second residue outputs;
a second residue stage, having a first input coupled to the first residue output of the first residue stage, a second input coupled to the second residue output of the first residue stage, a bit output, and first and second residue outputs; and
a third residue stage, having a first input coupled to the first residue output of the second residue stage, a second input coupled to the second residue output of the second residue stage, and a bit output, the third residue stage including a plurality of trim circuits, each trim circuit having a select input controlled by the bit output of two or more preceding residue stages in the sequence.

2. The analog-to-digital converter of claim 1, further comprising:
select logic, having inputs coupled to the bit outputs of the first and second residue stages, and having outputs coupled to the select inputs of the plurality of trim circuits of the third residue stage; and
digital circuitry having inputs coupled to bit outputs of the plurality of residue stages.

3. The analog-to-digital converter of claim 2, wherein the first residue stage is configured to generate its bit output at a first intermediate output or a second intermediate output;
wherein the second residue stage is configured to generate its bit output at a first intermediate output or a second intermediate output;
wherein the third residue stage is configured to generate its bit output at a first intermediate output or a second intermediate output;
and wherein each of the plurality of trim circuits in a first trim circuit group is coupled to the first intermediate output of the third residue stage, and each of the plurality of trim circuits in a second trim circuit group is are coupled to the second intermediate output of the third residue stage.

4. The analog-to-digital converter of claim 3, wherein the third residue stage comprises:
a delay comparator, having inputs coupled to the first and second residue outputs of the second residue stage, wherein the first and second intermediate outputs of the third residue stage are outputs of the delay comparator;
a first logic gate, having inputs coupled to the first and second intermediate outputs, wherein the first residue output of the third residue stage is an output of the first logic gate; and
a second logic gate, having inputs coupled to the first and second intermediate outputs, wherein the second residue output of the third residue stage is an output of the second logic gate;
wherein each of the plurality of trim circuits of the third residue stage includes a variable capacitor, a switch having a first terminal coupled to the variable capacitor, a second terminal coupled to one of the first and second intermediate outputs, and a control terminal coupled to an output of the select logic.

5. The analog-to-digital converter of claim 4, wherein each of the plurality of trim circuits in the first trim circuit group of the third residue stage is coupled to the first intermediate output, and each of the plurality of trim circuits in the second trim circuit group of the third residue stage is coupled to the second intermediate output;
wherein the select logic comprises a first layer of select logic gates including:
a first select logic gate having first and second inputs coupled to the first intermediate output of the first and second residue stages, respectively, and having an output coupled to a first trim circuit in each of the first and second trim circuit groups of the third residue stage;
a second select logic gate having first and second inputs coupled to the first intermediate output of the first residue stage and the second intermediate output of the second residue stage, respectively, and having an output coupled to a second trim circuit in each of the first and second trim circuit groups of the third residue stage;
a third select logic gate having first and second inputs coupled to the second intermediate output of the first residue stage and the first intermediate output of the second residue stage, respectively, and having an output coupled to a third trim circuit in each of the first and second trim circuit groups of the third residue stage; and
a fourth select logic gate having first and second inputs coupled to the second intermediate output of the first and second residue stages, respectively, and having an output coupled to a fourth trim circuit in each of the first and second trim circuit groups of the third residue stage.

6. The analog-to-digital converter of claim 5, further comprising:
a fourth residue stage, having a first input coupled to the first residue output of the third residue stage, a second input coupled to the second residue output of the third residue stage, first and second intermediate outputs, and first and second residue outputs, the fourth residue stage including a plurality of trim circuits, each trim circuit having a select input;
and wherein the select logic has inputs coupled to the first and second intermediate outputs of the third residue stage, and has outputs coupled to the select inputs of the plurality of trim circuits of the fourth residue stage.

7. The analog-to-digital converter of claim 6, wherein each of the plurality of trim circuits in a first trim circuit group of the fourth residue stage is coupled to the first intermediate output, and each of the plurality of trim circuits in a second trim circuit group of the fourth residue stage is coupled to the second intermediate output;
and wherein the select logic comprises a second layer of select logic gates, each select logic gate in the second layer having a first input coupled to an output of one of the select logic gates in the first layer, a second input coupled to one of the first and second intermediate outputs of the fourth residue stage, and an output coupled to the select input of one of the plurality of trim circuits in each of the first and second trim circuit groups of the fourth residue stage.

8. The analog-to-digital converter of claim 3, further comprising:
a fourth residue stage, having a first input coupled to the first residue output of the third residue stage, a second input coupled to the second residue output of the third residue stage, first and second intermediate outputs, and first and second residue outputs, the fourth residue stage including a plurality of trim circuits, each trim circuit having a select input;
and wherein the select logic has inputs coupled to the first and second intermediate outputs of the third residue stage, and outputs coupled to the select inputs of the plurality of trim circuits of the fourth residue stage.

9. The analog-to-digital converter of claim 3, wherein each of the plurality of trim circuits includes a variable capacitor, a switch having a first terminal coupled to the variable capacitor, a second terminal coupled to one of the first and second intermediate outputs, and a control terminal coupled to an output of the select logic;
wherein the analog-to-digital converter further comprises:
calibration circuitry having an input coupled to the digital output of the digital circuitry, having a digital output, a control output, and having outputs coupled to the variable capacitors of the plurality of trim circuits;
a digital-to-analog converter, having an input coupled to the digital output of the calibration circuitry, and having an analog output; and
an input multiplexer having a first input, a second input coupled to the analog output of the digital-to-analog converter, a control input coupled to the control output of the calibration circuitry, and an output coupled to the input of the voltage-to-delay circuit.

10. The analog-to-digital converter of claim 3, wherein the plurality of residue stages further comprises:
an over-range stage, having a first residue output coupled to a first input of the first residue stage and a second residue output coupled to a second input of the first residue stage.

11. An analog-to-digital converter, comprising:
a voltage-to-delay circuit configured to generate a delay signal at first and second outputs responsive to an input voltage; and
a time-to-digital circuit configured to generate a digital output word responsive to the delay signal from the voltage-to-delay circuit, the time-to-digital circuit comprising a plurality of residue stages coupled in a sequence;
wherein a first residue stage of the plurality of residue stages generates an output delay residue at a polarity based on a comparison of an input delay residue from a preceding residue stage in the sequence with a selected one of a plurality of independently controlled null delay thresholds, wherein the selected null delay threshold is selected responsive to the bit outputs of at least two preceding residue stages in the sequence and to the polarity of the input delay residue from the preceding residue stage.

12. The analog-to-digital converter of claim 11, wherein each of the plurality of residue stages is configured to generate a bit output responsive to a polarity of the input delay residue from a preceding residue stage in the sequence, and to generate an output delay residue for a next residue stage in the sequence.

13. The analog-to-digital converter of claim 12, further comprising:
calibration circuitry configured to, in a calibration mode, adjust each of the plurality of null delay thresholds of the first residue stage independently from others of the plurality of null delay thresholds.

14. The analog-to-digital converter of claim 12, wherein the plurality of residue stages further comprises a second residue stage later in the sequence than the first residue stage;
wherein the second residue stage generates its output delay residue at a polarity based on a comparison of its input delay residue with a selected one of a plurality of independently controlled null delay thresholds;
and wherein the selected null delay threshold in the second residue stage is selected responsive to the bit outputs of at least three preceding residue stages in the sequence and to the polarity of its input delay residue.

15. The analog-to-digital converter of claim 12, wherein the first residue stage includes a plurality of trim circuits;
and wherein the time-to-digital circuit further comprises:
select logic, configured to select one of the plurality of trim circuits of the first residue stage responsive to the bit outputs of the at least two preceding residue stages.

16. The analog-to-digital converter of claim 15, wherein the first residue stage is configured to generate a bit output at a first intermediate output or a second intermediate output;
wherein each of a first group of the plurality of trim circuits of the first residue stage is coupled to the first intermediate output, and each of a second group of the plurality of trim circuits is coupled to the second intermediate output;
and wherein the select logic selects one of the plurality of trim circuits in each of the first and second groups responsive to the bit outputs of the at least two preceding residue stages.

17. The analog-to-digital converter of claim 16, wherein the plurality of residue stages further comprises a second residue stage later in the sequence than the first residue stage, the second residue stage including a plurality of trim circuits and configured to generate a bit output at a first intermediate output or a second intermediate output;
wherein each of a first group of the plurality of trim circuits of the second residue stage is coupled to the first intermediate output, and each of a second group of the plurality of trim circuits of the second residue stage is coupled to the second intermediate output;
and wherein the select logic is further configured to select one of the plurality of trim circuits in each of the first and second groups of the second residue stage responsive to the bit outputs of the at least three preceding residue stages.

18. The analog-to-digital converter of claim 17, wherein the select logic comprises a first layer of select logic gates including:
a first select logic gate configured to output, to a first trim circuit in each of the first and second groups of trim circuits of the first residue stage, a logical combination of the first intermediate outputs of first and second preceding residue stages;
a second select logic gate configured to output, to a second trim circuit in each of the first and second groups of trim circuits of the first residue stage, a logical combination of the first intermediate output of the first preceding residue stage and the second intermediate output of the second preceding residue stage;
a third select logic gate configured to output, to a third trim circuit in each of the first and second groups of trim circuits of the fourth residue stage, a logical combination of the second intermediate output of the first preceding residue stage and the first intermediate output of the second preceding residue stage; and
a fourth select logic gate configured to output, to a fourth trim circuit in each of the first and second groups of trim circuits of the fourth residue stage, a logical combination of the second intermediate outputs of the first and second preceding residue stages;
and wherein the select logic further comprises a second layer of select logic gates, each select logic gate in the second layer configured to output, to the select input of one of the plurality of trim circuits of the second residue stage, a logical combination of an output of one of the select logic gates in the first layer and one of the first and second intermediate outputs of the first residue stage.

19. A system, comprising:
an analog front end having an input and an output;
an analog-to-digital converter, comprising:
a voltage-to-delay circuit having an input coupled to the output of the analog front end, and having first and second outputs;
a plurality of residue stages, comprising:
a first residue stage, having a bit output and first and second residue outputs;
a second residue stage, having a first input coupled to the first residue output of the first residue stage, a second input coupled to the second residue output of the first residue stage, a bit output, and first and second residue outputs;
a third residue stage, having a first input coupled to the first residue output of the second residue stage, a second input coupled to the second residue output of the second residue stage, and a bit output, the third residue stage including a plurality of trim circuits, each trim circuit having a select input controlled by the bit output of two or more preceding residue stages in the sequence.

20. The system of claim 19, wherein the analog-to-digital converter further comprises:
select logic, having inputs coupled to the bit outputs of the second and third residue stages, and having outputs coupled to the select inputs of the plurality of trim circuits of the fourth residue stage; and
digital circuitry having inputs coupled to bit outputs of the plurality of residue stages, and having a digital output; and
and further comprising:
a controller, having an input coupled to the digital output of the analog-to-digital converter.

21. The system of claim 20, wherein the first residue stage is configured to generate its bit output at a first intermediate output or a second intermediate output;
wherein the second residue stage is configured to generate its bit output at a first intermediate output or a second intermediate output;
wherein the third residue stage is configured to generate its bit output at a first intermediate output or a second intermediate output;
and wherein each of the plurality of trim circuits in a first trim circuit group is coupled to the first intermediate output of the third residue stage, and each of the plurality of trim circuits in a second trim circuit group is coupled to the second intermediate output of the third residue stage.

22. The system of claim 21, wherein the plurality of residue stages further comprises:
a fourth residue stage, having a first input coupled to the first residue output of the third residue stage, a second input coupled to the second residue output of the third residue stage, first and second intermediate outputs, and first and second residue outputs, the fourth residue stage including a plurality of trim circuits, each trim circuit having a select input;
and wherein the select logic has inputs coupled to the first and second intermediate outputs of the third residue stage, and outputs coupled to the select inputs of the plurality of trim circuits of the fourth residue stage.
